(19) United States
(12) Patent Application Publication
(10) Pub. No.: US 2025/0254809 A1
(43) Pub. Date: Aug. 7, 2025

(54) ELECTRONIC DEVICE

(71) Applicant: InnoLux Corporation, Miao-Li County (TW)

(72) Inventors: Chandra LIUS, Miao-Li County (TW); Yuan-Lin WU, Miao-Li County (TW); Kuan-Feng LEE, Miao-Li County (TW)

(73) Assignee: InnoLux Corporation, Miao-Li County (TW)

(21) Appl. No.: 18/988,838

(22) Filed: Dec. 19, 2024

(30) Foreign Application Priority Data
Feb. 1, 2024 (CN) 202410138036.X

(51) Int. Cl. H05K 5/02

(52) U.S. Cl. CPC H05K 5/0247

(57) ABSTRACT

An electronic device capable of operating in a first state or in a second state includes an electronic panel, an optical module, and a supporting plate. The electronic panel has a first portion and a second portion, wherein the first portion has a first active area and a second active area, a transmittance of the first active area is greater than a transmittance of the second active area, and the second portion is hidden from a top view in the first state and exposed from the top view in the second state. The optical module is disposed under the electronic panel and overlapped with the first active area in the first state. The supporting plate is disposed under the electronic panel, wherein the supporting plate has a first opening overlapped with the first active area and a plurality of second openings overlapped with the second portion.

### BACKGROUND OF THE DISCLOSURE

### 1. Field of the Disclosure

The present disclosure relates to an electronic device, and more particularly to a stretchable electronic device.

### 2. Description of the Prior Art

When optical elements are applied to flexible electronic devices, the light receiving effect of the optical elements may be affected by the change of degree of flexibility of the flexible electronic device, thereby affecting the functions of the optical elements. Therefore, to reduce the above-mentioned problem is still an important issue in the present field.

### SUMMARY OF THE DISCLOSURE

One of the purposes of the present disclosure is to provide a flexible electronic device having an optical module.

An electronic device capable of operating in a first state or in a second state is provided by the present disclosure. The electronic device includes an electronic panel, an optical module, and a supporting plate. The electronic panel has a first portion and a second portion, wherein the first portion has a first active area and a second active area, a transmittance of the first active area is greater than a transmittance of the second active area. The second portion is hidden from a top view of the electronic device in the first state and exposed from the top view of the electronic device in the second state. The optical module is disposed under the electronic panel and overlapped with the first active area in the first state. The supporting plate is disposed under the electronic panel, wherein the supporting plate has a first opening overlapped with the first active area and a plurality of second openings overlapped with the second portion.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a cross-sectional view of an electronic device according to a first embodiment of the present disclosure.

FIG. 2 schematically illustrates a bottom view of the electronic device according to the first embodiment of the present disclosure.

FIG. 3 schematically illustrates an operating process of the electronic device according to the first embodiment of the present disclosure.

FIG. 4 schematically illustrates a cross-sectional view of an electronic device according to a second embodiment of the present disclosure.

FIG. 5 schematically illustrates a bottom view of the electronic device according to the second embodiment of the present disclosure.

FIG. 6 and FIG. 7 schematically illustrate cross-sectional views of an electronic device according to a third embodiment of the present disclosure.

FIG. 8 schematically illustrates a bottom view of the electronic device according to the third embodiment of the present disclosure.

FIG. 9 schematically illustrates an operating process of the electronic device according to the third embodiment of the present disclosure.

FIG. 10 schematically illustrates a cross-sectional view of an electronic device according to a fourth embodiment of the present disclosure.

FIG. 11 schematically illustrates a bottom view of the electronic device according to the fourth embodiment of the present disclosure.

FIG. 12 and FIG. 13 schematically illustrate cross-sectional views of an electronic device according to a fifth embodiment of the present disclosure.

FIG. 14 and FIG. 15 schematically illustrate cross-sectional views of an electronic device according to a sixth embodiment of the present disclosure.

FIG. 16 schematically illustrates a bottom view of an electronic device according to a seventh embodiment of the present disclosure.

FIG. 17 schematically illustrates a top view of an electronic element of an electronic device according to an eighth embodiment of the present disclosure.

FIG. 18 schematically illustrates an electronic device according to a ninth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

According to the present disclosure, the thickness, length and width may be measured through optical microscope, and the thickness or width may be measured through the cross-sectional view in the electron microscope, but not limited thereto.

In addition, any two values or directions used for comparison may have certain errors. In addition, the terms “equal to”, “equal”, “the same”, “approximately” or “substantially” are generally interpreted as being within ±20%, ±10%, ±5%, ±3%, ±2%, ±1%, or ±0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may include a display device, a sensing device, a back-light device, an antenna device, a tiled device or other suitable electronic devices, but not limited thereto. The electronic device of the present disclosure may be a foldable electronic device, a flexible electronic device or a stretchable electronic device. The display device may include a non-self-emissive display device or a self-emissive display device. The non-self-emissive display device for example includes a liquid crystal display device, but not limited thereto. The self-emissive display device for example includes a light emitting diode display device, but not limited thereto. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The sensing device may include a biosensor, a touch sensor, a fingerprint sensor, other suitable sensors or combinations of the above-mentioned sensors. The antenna device may for example include a liquid crystal antenna device, but not limited thereto. The tiled device may for example include a tiled display device or a tiled antenna device, but not limited thereto. The outline of the electronic device may be a rectangle, a circle, a polygon, a shape with curved edge or other suitable shapes. The electronic device may include electronic units, wherein the electronic units may include passive elements or active elements, such as capacitor, resistor, inductor, diode, transistor, sensors, and the like. The diode may include a light emitting diode or a photo diode. The light emitting diode may for example include an organic light emitting diode (OLED) or an inorganic light emitting diode. The inorganic light emitting diode may for example include a mini light emitting diode (mini LED), a micro light emitting diode (micro LED) or a quantum dot light emitting diode (QLED), but not limited thereto. It should be noted that the electronic device of the present disclosure may be combinations of the above-mentioned devices, but not limited thereto. The electronic device may include peripheral systems such as driving systems, controlling systems, light source systems to support display devices, antenna devices, wearable devices (such as augmented reality devices or virtual reality devices), vehicle devices (such as windshield of car) or tiled devices. The display device is taken as an example of the electronic device for describing the contents of the present disclosure in the following, but the present disclosure is not limited thereto.

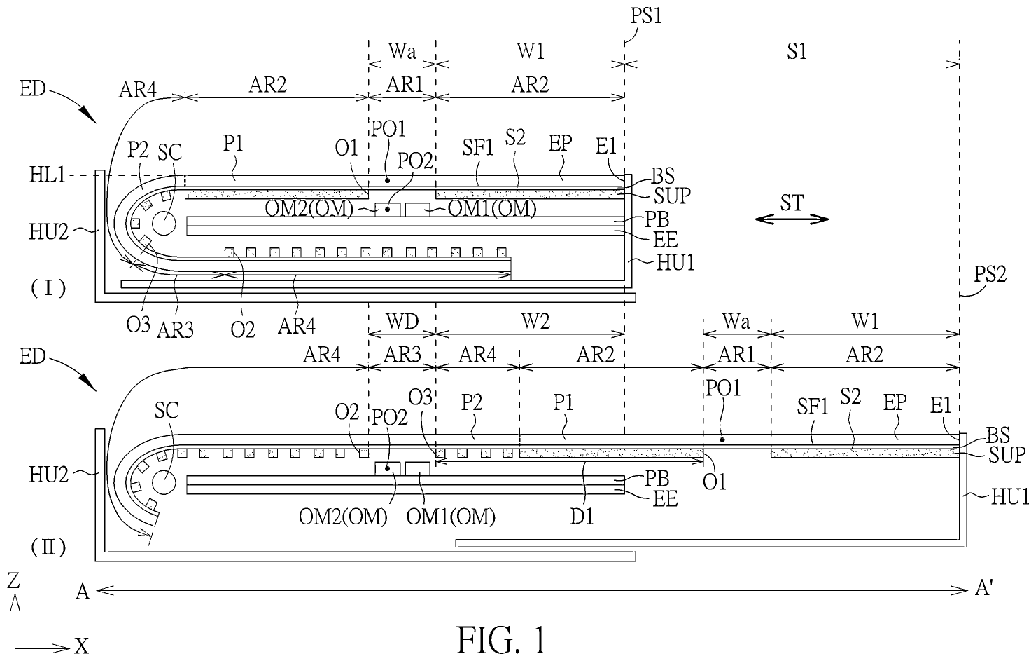

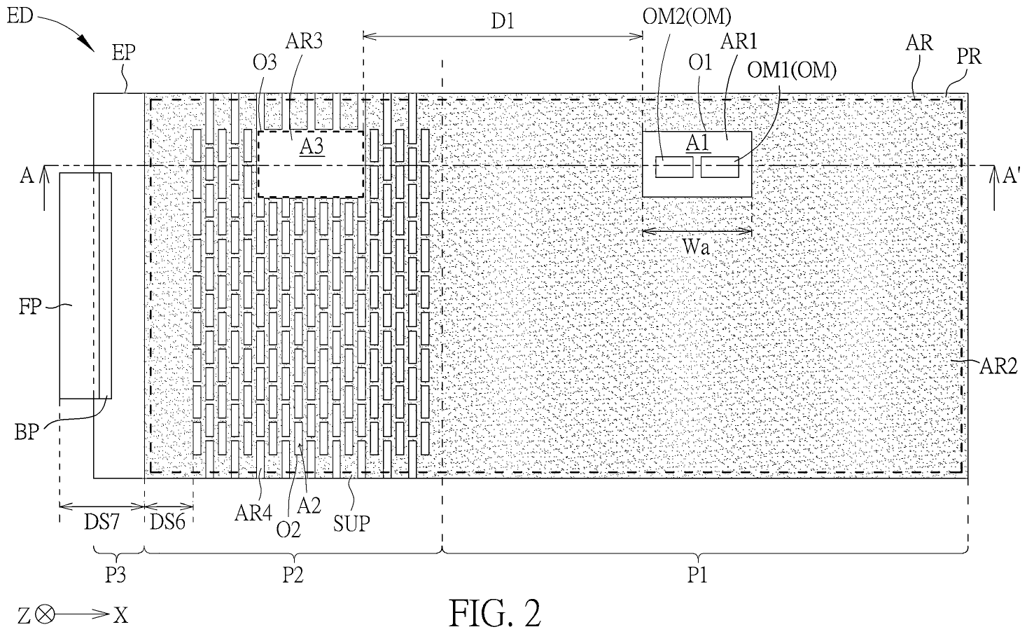

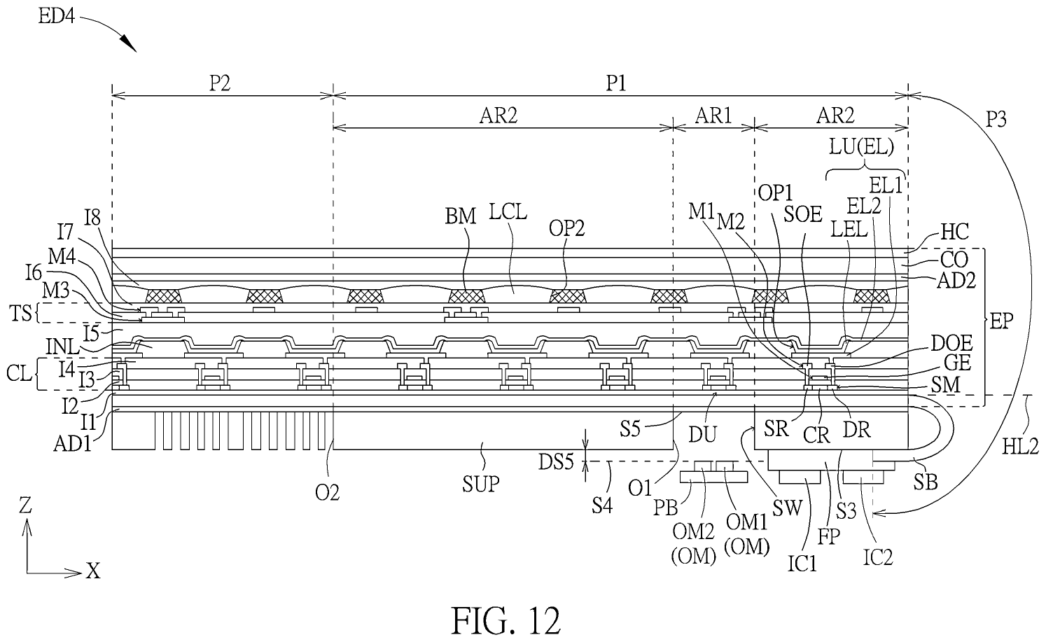

Referring to FIG. 1 and FIG. 2, FIG. 1 schematically illustrates a cross-sectional view of an electronic device according to a first embodiment of the present disclosure, and FIG. 2 schematically illustrates a bottom view of the electronic device according to the first embodiment of the present disclosure. Specifically, FIG. 1 shows the cross-sectional structure of the electronic device ED shown in FIG. 2 along a section line A-A′. According to the present embodiment, the electronic device ED may include an electronic panel EP, optical modules OM and a supporting plate SUP, but not limited thereto. The optical modules OM and the supporting plate SUP are disposed under the electronic panel EP. In detail, the electronic device ED may include a base BS, and the electronic panel EP may be disposed on a surface SF1 of the base BS. The base BS may include a flexible material or at least partially include a flexible material. The flexible material may for example include polyimide (PI), polycarbonate (PC), polyethylene terephthalate (PET), other suitable materials or combinations of the above-mentioned materials. In some embodiments, the base BS may include a combination of a flexible material and a rigid material. The rigid material for example includes glass, quartz, sapphire, ceramic, other suitable materials or combinations of the above-mentioned materials. The supporting plate SUP is disposed at a side of the base BS opposite to the electronic panel EP. Specifically, the supporting plate SUP may be located at a side of a surface S2 of the base BS. The supporting plate SUP may for example be attached to the surface S2 of the base BS through an adhesive layer (not shown), but not limited thereto. It should be noted that in some embodiments, the base BS may be regarded as a portion of the electronic panel EP, such as a portion of the substrate SB (shown in FIG. 12) of the electronic panel EP, and the supporting plate SUP may be regarded as being attached to a side of the electronic panel EP. The supporting plate SUP may provide supporting effect to the elements or the layers (such as the electronic panel EP) disposed thereon. The optical modules OM and the supporting plate SUP may be located at the same side of the electronic panel EP. A side of the electronic panel EP opposite to the supporting plate SUP may be defined as the active side of the electronic panel EP, and the other side of the electronic panel EP may be defined as the non-active side, wherein the optical modules OM and the supporting plate SUP may be located at the non-active side of the electronic panel EP. In addition, the optical modules OM may be located at a side of the supporting plate SUP opposite to the electronic panel EP. It should be noted that in order to simplify the figure, the electronic panel EP is just shown as a single layer in FIG. 1, and the detailed structure of the electronic panel EP is not shown in FIG. 1. In addition, FIG. 2 just shows the electronic panel EP and the supporting plate SUP of the electronic device ED, and other elements or layers are omitted. The detailed structures of the elements or the layers of the electronic device ED will be detailed in the following.

The electronic panel EP of the present disclosure may include any suitable type of panel, according to the type or use of the electronic device ED. In some embodiments, the electronic device ED may include a display device, and the electronic panel EP may include a display panel. In some embodiments, the electronic panel EP may include a sensing panel, an antenna panel or other suitable panels. In some embodiments, the electronic panel EP may include combinations of display panel and other panels. The electronic device ED including the display panel is taken as an example for describing the structure of the electronic panel EP of the present disclosure in the following, but the present disclosure is not limited thereto.

The structure of the electronic panel EP of the present disclosure may refer to FIG. 12. As shown in FIG. 12, the electronic panel EP may include a substrate SB, a circuit layer CL disposed on the substrate SB, and electronic elements EL disposed on the circuit layer CL, but not limited thereto. The substrate SB may be used for supporting the elements and the layers disposed thereon. The substrate SB may include a flexible material or at least partially include a flexible material. In some embodiments, the substrate SB may include combinations of flexible material and rigid material. The flexible material and the rigid material described herein may refer to the contents above. The material of the substrate SB may be the same as or different from the material of the base BS. It should be noted that in some embodiments, the substrate SB shown in FIG. 12 may be the base BS shown in FIG. 1, that is, the substrate SB and the base BS are actually the same layer. In some embodiments, the substrate SB may include a multi-layer structure, and one of the layers in the multi-layer structure (such as the lowest layer) may be the base BS. In other words, the base BS may be regarded as the substrate SB or a portion of the substrate SB of the electronic panel EP. In such condition, the supporting plate SUP may be regarded as being disposed at a side of the substrate SB or at a side of the base BS. The supporting plate SUP may for example be attached to the substrate SB or the base BS through an adhesive layer AD1, but not limited thereto.

The circuit layer CL may include various kinds of wires, circuits or electronic units that can be applied to the electronic device ED. The electronic unit may include any suitable active element and/or passive element. The circuit layer CL may include any suitable structure formed by stacking conductive layer(s) and insulating layer(s), wherein the conductive layer (s) may be used for forming the wires, the circuits or the electronic units mentioned above. For example, as shown in FIG. 12, the circuit layer CL may include driving units DU, wherein the driving units DU may be electrically connected to any suitable electronic element (such as the electronic elements EL) in the electronic panel EP, but not limited thereto. The driving unit DU may include transistor(s), such as thin film transistor(s) (TFT). Specifically, the circuit layer CL may include a semiconductor layer SM, a conductive layer M1 and a conductive layer M2, wherein the semiconductor layer SM may form the channel region CR, the source region SR and the drain region DR of the driving unit DU, and the conductive layer M1 may form the gate electrode GE of the driving unit DU. The channel region CR may be defined as the portion of the semiconductor layer SM overlapping the gate electrode GE. The conductive layer M2 is located on the conductive layer M1, and the conductive layer M2 may form the source electrode SOE and the drain electrode DOE respectively be electrically connected to the source region SR and the drain region DR. The semiconductor layer SM may include a semiconductor material. The semiconductor material may include silicon or metal oxides, such as low temperature polysilicon (LTPS) semiconductor, amorphous silicon (a-Si) semiconductor, indium gallium zinc oxide (IGZO) semiconductor, low temperature polysilicon oxide (LTPO) semiconductor or combinations of the above-mentioned materials, but not limited thereto. The conductive layer M1 and the conductive layer M2 may include any suitable conductive material, such as metals, but not limited thereto. The circuit layer CL may further include an insulating layer 12 disposed between the semiconductor layer SM and the conductive layer M1, an insulating layer 13 disposed between the conductive layer M1 and the conductive layer M2 and an insulating layer 14 disposed on the insulating layer 13. The insulating layer 12, the insulating layer 13 and the insulating layer 14 may include any suitable insulating material. The insulating layer 12 may be the gate insulating layer of the driving unit DU. It should be noted that the circuit layer CL may further include other suitable elements or layers, which is not limited to what is shown in FIG. 12. In some embodiments, the electronic panel EP may further include an insulating layer I1 disposed between the substrate SB and the circuit layer CL. The insulating layer I1 may serve as the buffer layer, but not limited thereto.

The electronic element EL may include a light emitting unit LU, but not limited thereto. The light emitting unit LU may include a self-emissive light emitting element or a non-self-emissive light emitting element. The non-self-emissive light emitting element may for example include a liquid crystal layer, but not limited thereto. The self-emissive light emitting element may include a light emitting diode, but not limited thereto. The light emitting diode may include an organic light emitting diode (OLED), a quantum dot light emitting diode (QLED or QDLED), an inorganic light emitting diode, other suitable light emitting elements or combinations of the above-mentioned elements. The inorganic light emitting diode may for example include a mini light emitting diode (mini LED) or a micro light emitting diode (micro LED), but not limited thereto. The light emitting unit LU shown in FIG. 12 for example includes an organic light emitting diode, but not limited thereto. Specifically, the light emitting unit LU may include an electrode EL1, an electrode EL2 and a light emitting layer LEL disposed between the electrode EL1 and the electrode EL2. The electrode EL1 may be disposed on the insulating layer 14 of the circuit layer CL, the light emitting layer LEL may be disposed on the electrode EL1, and the electrode EL2 may be disposed on the light emitting layer LEL. The electronic panel EP may further include an insulating layer INL disposed on the insulating layer 14, wherein the insulating layer INL may partially cover the electrode EL1 and may expose a portion of the electrode EL1. The insulating layer INL may include a plurality of openings OP1, and the light emitting layer LEL may be disposed corresponding to the openings OP1, or the light emitting layer LEL may be disposed in the openings OP1. The insulating layer INL may serve as the pixel defining layer (PDL). The electrode EL2 may be a continuous layer conformally disposed on the light emitting layer LEL and the insulating layer INL, that is, the electrodes EL2 of different light emitting units LU may be connected to each other, but not limited thereto. The electrode EL1 may be electrically connected to the driving unit DU (such as the drain electrode DOE of the driving unit DU), such that the light emitting unit LU is electrically connected to the driving unit DU. The electronic panel EP may further include an insulating layer I5 disposed on the light emitting units LU, wherein the insulating layer I5 may be disposed on the electrode EL2. The insulating layer I5 may serve as the encapsulation layer for encapsulating the elements and the layers disposed there below. The insulating layer I5 may further provide a flat top surface to facilitate the disposition of other elements and layers on the insulating layer I5.

In some embodiments, the electronic panel EP may further include a touch structure TS disposed on the light emitting units LU. The touch structure TS may include a structure formed by stacking conductive layer(s) and insulating layer(s), but not limited thereto. As shown in FIG. 12, the touch structure TS may include a conductive layer M3 disposed on the insulating layer I5, an insulating layer 16 disposed on the conductive layer M3, a conductive layer M4 disposed on the insulating layer 16 and an insulating layer 17 disposed on the conductive layer M4. The conductive layer M4 may be electrically connected to the conductive layer M3 through the vias penetrating the insulating layer 16. The conductive layer M3 and the conductive layer M4 may include any suitable conductive material, such as metals, but not limited thereto. The patterns of the conductive layers (such as the conductive layer M3 and the conductive layer M4) of the touch structure TS may not overlap the light emitting units LU (or not overlap the light emitting regions of the light emitting layers LEL of the light emitting units LU) in the normal direction (that is, the direction Z, which will not be redundantly described in the following) of the electronic device ED. It should be noted that the structure and disposition position of the touch structure TS shown in FIG. 12 are exemplary, and the present disclosure is not limited thereto. The touch structure TS may include a resistive touch structure, a capacitive touch structure, an infrared touch structure, an ultrasonic touch structure, other suitable touch structures or combinations of the above-mentioned touch structures.

In some embodiments, the electronic device ED may further include light converting layers LCL and a black matrix layer BM disposed on the light emitting units LU. The light converting layer LCL may include any suitable material capable of converting the wavelength or the color of the light passing through the light converting layer LCL. For example, the light converting layer LCL may include a color filter, but not limited thereto. In some embodiments, the light converting layer LCL may include quantum dot, fluorescent, phosphorescent, other suitable materials or combinations of the above-mentioned materials. The electronic panel EP may include a plurality of light converting layers LCL, wherein the plurality of light converting layers LCL may convert the lights into the lights of different wavelengths or colors. For example, the light converting layers LCL may respectively convert lights into a red light, a green light and a blue light which can be mixed into a white light, but not limited thereto. The light converting layers LCL may be disposed corresponding to the light emitting units LU. The black matrix layer BM may be disposed between two adjacent light converting layers LCL. Specifically, the black matrix layer BM may include a plurality of openings OP2, and the light converting layers LCL may be disposed corresponding to the openings OP2 of the black matrix layer BM. In some embodiments, the electronic panel EP may further include an insulating layer 18 disposed on the light converting layers LCL and the black matrix layer BM. The insulating layer 18 may provide a flat top surface to facilitate the disposition of other elements or layers on the insulating layer 18.

In some embodiments, the electronic panel EP may further include a cover layer CO disposed on the light emitting units LU. Specifically, the cover layer CO may be attached to the insulating layer 18 through an adhesive layer AD2. It should be noted that the cover layer CO may include a multi-layer structure, such as a multi-layer structure formed by stacking an inorganic layer, an organic layer and an inorganic layer.

In some embodiments, the electronic panel EP may further include a hard coating layer HC disposed on the cover layer CO. The hard coating layer HC may be disposed at a side of the cover layer CO opposite to the light converting layers LCL. The hard coating layer HC may provide protection to the elements and the layers disposed there below.

The structure of the electronic panel EP shown in FIG. 12 may be applied to the electronic devices ED in the embodiments of the present disclosure. However, the electronic panels EP in the embodiments may respectively include any suitable structure according to the demands of design of the electronic device ED, which are not limited to what is shown in FIG. 12. In order to simplify the figures, the electronic panel EP is shown as a single layer in FIG. 1 and other figures.

According to the present disclosure, the optical module OM may include any suitable optical sensing element, such as a visible light sensing element or a non-visible light sensing element. The optical sensing element may for example include an optical sensor, an optical distance sensor, an optical fingerprint sensor, a camera or other suitable optical sensing elements. The electronic device ED may include a plurality of optical modules OM, but not limited thereto. For example, as shown in FIG. 1, the electronic device ED may include an optical module OM1 and an optical module OM2, wherein the optical module OM1 and the optical module OM2 may respectively include any one of the above-mentioned optical sensing elements, but not limited thereto. The optical module OM1 and the optical module OM2 may include the same optical sensing element and different optical sensing elements. In some embodiments, the optical module OM1 may include a camera, and the optical module OM2 may include an optical sensor. In some embodiments, the optical module OM1 may include a visible light sensing element, and the optical module OM2 may include an infrared sensing element. In some embodiments, the electronic device ED may include one optical module OM or more than two optical modules OM. Since the optical modules OM may be disposed under the electronic panel EP in the present disclosure, the electronic device ED may for example be a camera under display device, but not limited thereto.

According to the present disclosure, the electronic device ED may further include a circuit board PB, wherein the optical modules OM may be disposed on the circuit board PB. Specifically, the optical modules OM may be bonded on the circuit board PB, thereby being electrically connected to the circuit board PB. As shown in FIG. 1, the circuit board PB may be located at a side of the supporting plate SUP opposite to the electronic panel EP. Other suitable electronic elements (such as a control unit (not shown)) may further be disposed on the circuit board PB, wherein the control unit may be electrically connected to the optical modules OM through the circuit board PB. Therefore, the operation of the optical modules OM may be controlled through the control unit. The circuit board PB may include a flexible printed circuit board (FPCB), but not limited thereto. In some embodiments, a control unit for controlling the light emitting units LU of the electronic panel EP may further be disposed on the circuit board PB, but not limited thereto.

In some embodiments, the electronic device ED may further include an element layer EE, wherein the element layer EE may be disposed at a side of the circuit board PB opposite to the optical modules OM. In other words, the circuit board PB may be disposed between the optical modules OM and the element layer EE. In some embodiments, the element layer EE may directly contact the circuit board PB. In some embodiments, other layers may be included between the element layer EE and the circuit board PB. The element layer EE may include a battery mainboard, an inner frame of the electronic device ED or other suitable elements.

According to the present disclosure, the electronic device ED may be a flexible electronic device and have an unfolding state (or a stretching state) and/or a folding state (or a non-stretching state). Specifically, the electronic panel EP of the electronic device ED may be unfolded (or expanded) and/or folded (or closed). For example, as shown in FIG. 1, the electronic device ED may further include a housing HU1, wherein the housing HU1 may be disposed outside the elements such as the electronic panel EP, the optical modules OM, and the like. The electronic panel EP may be connected to the housing HU1. “The electronic panel EP is connected to the housing HU1” described herein may represent that the electronic panel EP is directly or indirectly connected to the housing HU1. In some embodiments, the electronic panel EP may directly contact the housing HU1. In some embodiments, the electronic panel EP and the housing HU1 may be connected to each other through other elements. In the present embodiment, the housing HU1 may move in an unfolded-folded direction ST, such that the electronic panel EP connected to the housing HU1 may also move in the unfolded-folded direction ST as the housing HU1 expands or closes, thereby achieving unfold and/or fold of the electronic panel EP. The unfolded-folded direction ST may be parallel to the direction X in the present embodiment, which for example includes the direction X and the direction −X. Specifically, as shown in FIG. 1, when the user does not move the housing HU1, the electronic panel EP may not be stretched, and the electronic device ED may be regarded as being in the folding state (or a closed state), as shown in the state (I). When the user moves the housing HU1 along the direction X, the electronic panel EP connected to the housing HU1 may move (or be stretched) along the direction X, such that the electronic panel EP may be unfolded (or expanded), as shown in the state (II). In such condition, the electronic device ED may be regarded as being in the unfolding state. In addition, the housing HU1 may move along the direction −X, such that the electronic panel EP may move along the direction −X. In FIG. 1, the state (I) may be the folding state of the electronic device ED, and the state (II) may be the unfolding state of the electronic device ED. In other words, the electronic device ED may be switched between the folding state and the unfolding state by moving the electronic panel EP along the unfolded-folded direction ST. It should be noted that “the unfolding state of the electronic device ED” mentioned above may include the embodiment that the electronic device ED is partially unfolded (or partially expanded), which is not limited to the condition that the electronic device ED is completely unfolded (or expanded). In addition, the stretching way of the electronic panel EP mentioned above is exemplary, and the present disclosure is not limited thereto.

In some embodiments, the electronic device ED may further include a housing HU2, wherein the housing HU2 may be disposed outside the elements such as the electronic panel EP, the optical modules OM, the housing HU1, and the like. The housing HU1 and the housing HU2 may provide protection to the elements or the layers inside the housing HU1 and the housing HU2. The housing HU1 and the housing HU2 may include any suitable protecting material. The materials of the housing HU1 and the housing HU2 may be the same or different from each other, it is not limited in the present disclosure. The relative position of the housing HU1 and the housing HU2 may change as the electronic device ED switches between the unfolding state and the folding state.

According to the present disclosure, the electronic panel EP may include a first portion P1 and a second portion P2, wherein the first portion P1 and the second portion P2 are connected to each other. The first portion P1 may be called as the flat portion of the electronic panel EP, and the second portion P2 may be called as the flexible portion of the electronic panel EP. Specifically, the portion of the electronic panel EP that remains flat during the folding or unfolding process of the electronic device ED may be defined as the first portion P1 of the electronic panel EP. That is, the first portion P1 may not be rolled, or the degree of rolling of the first portion P1 may not be changed due to unfolding and/or folding of the electronic device ED. The portion of the electronic panel EP that can be rolled or deformed in other ways during the folding or unfolding process of the electronic device ED may be defined as the second portion P2 of the electronic panel EP. In detail, as shown in FIG. 1, the second portion P2 of the electronic panel EP may surround a scroll SC and be rolled, and the part of the second portion P2 that is rolled may change as the electronic panel EP moves, thereby achieving folding and/or unfolding of the electronic device ED. Specifically, the electronic panel EP may surround the scroll SC and be rolled, such that the electronic panel EP may surround the elements such as the optical modules OM, the circuit board PB, and the like. In other words, the second portion P2 may be rolled or unfolded (expanded) as the electronic panel EP moves along the unfolded-folded direction ST, and as the degree of unfolding of the electronic panel EP becomes different, the rolled part of the second portion P2 may change accordingly. The first portion P1 and the second portion P2 may be defined under the folding state (or the non-stretching state) of the electronic device ED. For example, in the state (I) shown in FIG. 1, the portion of the electronic panel EP starts to be deviated from a horizontal extending line HL1 parallel to a surface of the electronic panel EP may be defined as the portion P2, but not limited thereto. In the state (I), the optical modules OM and the circuit board PB may for example be located between the first portion P1 and the second portion P2.

The second portion P2 may be hidden from a top view of the electronic device ED in the folding state of the electronic device ED, and the second portion P2 may be exposed from the top view of the electronic device ED in the unfolding state of the electronic device ED. The first portion P1 may be exposed from the top view of the electronic device ED in the folding state or in the unfolding state of the electronic device ED. “The second portion P2 is exposed in the unfolding state of the electronic device ED” mentioned above may include the embodiment that at least a part of the second portion P2 is exposed. “The second portion P2 is hidden” mentioned above may represent that the second portion P2 is not observed by the user or cannot be operated by the user when the user uses the electronic device ED. In other words, the second portion P2 is the portion which is hidden in a first state and exposed in a second state when the user observes the electronic device ED in a top view. For example, when the electronic device ED is in the folding state, the second portion P2 may be shielded by any suitable element or layer (such as the housing HU2, but not limited thereto) in the electronic device ED and cannot be observed or operated by the user. Therefore, when the electronic device ED is in the folding state, the second portion P2 of the electronic panel EP may not be observed by the user, and the user may operate the first portion P1 of the electronic panel EP; and when the electronic device ED is in the unfolding state, the second portion P2 of the electronic panel EP may at least be partially observed by the user, and the user may operate the first portion P1 and the exposed part of the second portion P2 of the electronic panel EP. “The first portion P1 and the second portion P2 of the electronic panel EP” described in the following may refer to the contents mentioned above, and will not be redundantly described. It should be noted that in some embodiments, as shown in FIG. 1, the edge of the second portion P2 away from the first portion P1 may not be aligned with the edge of the supporting plate SUP. In some embodiments, as shown in FIG. 2, the edge of the second portion P2 away from the first portion P1 may be aligned with the edge of the supporting plate SUP.

As shown in FIG. 2, according to the present disclosure, the electronic panel EP may have an active area AR and a peripheral area PR. The active area AR may be the area where the electronic elements of the electronic panel EP is operated or the area that can be operated by the user. Specifically, the active area AR may be defined as the area of the electronic panel EP that performs specific functions. For example, the active area AR may for example include a display area, a sensing area or a signal receiving-emitting area, according to the type of the electronic device ED, but not limited thereto. The active area AR may be defined through the electronic elements (such as the electronic elements EL or the light emitting units LU shown in FIG. 12) of the electronic panel EP. Specifically, the active area AR may be defined as the minimum rectangle enclosed by the outer edges of the outermost electronic elements, but not limited thereto. After the active area AR is defined, the other area of the electronic panel EP except for the active area AR may be defined as the peripheral area PR. It should be noted that the ranges of the active area AR and the peripheral area PR shown in FIG. 2 are exemplary, and the present disclosure is not limited thereto.

In the present embodiment, as shown in FIG. 1 and FIG. 2, the first portion P1 of the electronic panel EP has a first active area AR1 and a second active area AR2, wherein a transmittance of the first active area AR1 is greater than a transmittance of the second active area AR2. “The transmittance” described herein may indicate the transmittance of the light received by the optical modules OM. The combination of the first active area AR1 and the second active area AR2 may be a portion of the active area AR corresponding to the first portion P1. The first portion P1 may further include a portion of the peripheral area PR in addition to the first active area AR1 and the second active area AR2, as shown in FIG. 2. It should be noted that in order to simplify the figure, the peripheral area PR in the first portion P1 is omitted in FIG. 1. Specifically, the portion of the active area AR corresponding to the first portion P1 may include two areas having different transmittances, wherein one of the two areas having a greater transmittance may be the first active area AR1, and another one of the two areas having a lower transmittance may be the second active area AR2. The difference in transmittance between the first active area AR1 and the second active area AR2 may for example be achieved through the design of the electronic elements EL (shown in FIG. 12). For example, the density and/or size of the electronic elements EL corresponding to the first active area AR1 may be lower than the density and/or size of the electronic elements EL corresponding to the second active area AR2, but not limited thereto. As shown in FIG. 2, the second active area AR2 may surround the first active area AR1 in the normal direction of the electronic device ED, but not limited thereto. The positions of the first active area AR1 and the second active area AR2 are not limited to what is shown in FIG. 2.

In the present embodiment, the second portion P2 of the electronic panel EP may have a third active area AR3, wherein a transmittance of the third active area AR3 may be greater than the transmittance of the second active area AR2 of the first portion P1. Specifically, a portion of the active area AR corresponding to the second portion P2 may include two areas having different transmittances, wherein one of the two areas having a greater transmittance may be the third active area AR3, and another one of the two areas having a lower transmittance may be an active area AR4. The second portion P2 may further include a portion of the peripheral area PR in addition to the third active area AR3 and the active area AR4. In order to simplify the figure, the portion of the peripheral area PR in the second portion P2 is omitted in FIG. 1. The transmittance of the second active area AR2 may be the same as the transmittance of the active area AR4, and the transmittance of the third active area AR3 is greater than the transmittance of the active area AR4. In other words, the active area AR of the electronic panel EP may include an area (including the second active area AR2 and the active area AR4) having a transmittance and the first active area AR1 and the third active area AR3 having other transmittances greater than the transmittance. The transmittance of the first active area AR1 may be the same as the transmittance of the third active area AR3, but not limited thereto.

According to the present embodiment, as shown in FIG. 1, when the electronic device ED is unfolded and/or folded, the relative position between the electronic panel EP and the optical module OM would change. Specifically, when the electronic device ED is in the folding state (the state (I)), a point PO1 may be defined in the electronic panel EP, and a point PO2 may be defined in the optical module OM, wherein the point PO1 corresponds to the point PO2. In other words, in the normal direction of the electronic device ED, the point PO1 may overlap the point PO2. After that, when the electronic device ED is in the unfolding state (the state (II)), the point PO1 in the electronic panel EP may not correspond to the point PO2 in the optical module OM, or the point PO1 is not overlapped with the point PO2 in the normal direction of the electronic device ED. For example, the optical module OM may not move as the electronic device ED is unfolded and/or folded in the present embodiment, that is, the optical module OM is located in a fixed position whether the electronic device ED is unfolded and/or folded, but not limited thereto. In some embodiments, the optical module OM may move along the unfolded-folded direction ST as the electronic device ED is unfolded and/or folded, and the degree of movement of the optical module OM may be different from the degree of movement of the electronic panel EP, such that the relative position between the electronic panel EP and the optical module OM is changed. In such condition, the optical module OM may directly or indirectly be connected to the housing HU1, thereby making the optical module OM movable, but not limited thereto.

According to the present embodiment, the electronic device ED may operate in a first state and in a second state, wherein when the electronic device ED is in the first state, the optical module OM may correspond to the first active area AR1 of the first portion P1; and when the electronic device ED is in the second state, the optical module OM may correspond to the third active area AR3 of the second portion P2. In other words, in the normal direction of the electronic device ED, the first active area AR1 may overlap the optical module OM in the first state of the electronic device ED, and the third active area AR3 may overlap the optical module OM in the second state of the electronic device ED. The “first state” described herein is the folding state of the electronic device ED. In other words, when the electronic device ED is in the folding state (as shown in the state (I) of FIG. 1), the disposition position of the optical module OM may correspond to the first active area AR1. Specifically, when the electronic device ED is in the folding state, the optical module OM may correspond to the first portion P1 (or the flat portion) of the electronic panel EP. By making the optical module OM corresponding to the first active area AR1 which has a greater transmittance in the first portion P1, the light receiving effect of the optical module OM may be improved. In such condition, the range of the first active area AR1 may be determined according to the disposition position of the optical module OM. In the present embodiment, the electronic device ED may include an optical module OM or a plurality of optical modules OM, and the range of the first active area AR1 may overlap the optical module OM or the plurality of optical modules OM in the normal direction of the electronic device ED.

As mentioned above, when the electronic device ED of the present embodiment changes from the first state to the second state, the relative position between the electronic panel EP and the optical module OM would change. In such condition, the optical module OM may be deviated from the first active area AR1, that is, the first active area AR1 may not overlap the optical module OM. According to the present embodiment, the electronic device ED may be configured to operate in the second state in addition to in the first state (that is, the folding state) mentioned above. The “second state” described herein may be a state that the electronic device ED is unfolded (or expanded) and the optical module OM corresponds to the third active area AR3 of the second portion P2. Specifically, when the electronic device ED is unfolded (or expanded) such that the optical module OM corresponds to the third active area AR3, the electronic device ED is said to be in the second state. In the second state, the degree of expansion of the electronic device ED may be determined according to the design of the electronic device ED. The first state and the second state may respectively refer to the state (I) and the state (II) in FIG. 1.

In short, the electronic device ED may operate in the first state and in the second state, wherein the electronic device ED is folded in the first state and unfolded (expanded) in the second state. The second portion P2 of the electronic panel EP is hidden from the top view of the electronic device ED and the exposed from the top view of the electronic device ED in the second state. The optical module OM may respectively correspond to the first active area AR1 and the third active area AR3 with greater transmittances in the first state and in the second state. Therefore, the light receiving effect of the optical module OM may be improved in different states of the electronic device ED.

In the present embodiment, the optical module OM may be designed to perform its function at least in the first state and in the second state of the electronic device ED. Specifically, when the electronic device ED is folded (in the first state), the optical module OM may correspond to the first active area AR1 and perform its function; and when the electronic device ED is unfolded, the optical module OM may perform its function when the optical module OM corresponds to the third active area AR3, that is, the optical module OM may perform its function in the second state of the electronic device ED. In other words, the second state of the electronic device ED may also be regarded as the state that the electronic device ED is unfolded (or expanded) and the optical module OM is capable of performing its function.

In the present embodiment, the arrangement direction of the first active area AR1 and the third active area AR3 may parallel to the unfolded-folded direction ST, that is, the first active area AR1 and the third active area AR3 may be arranged in a direction parallel to the direction X, but not limited thereto. Therefore, when the electronic panel EP is folded and/or unfolded along the unfolded-folded direction ST, the optical module OM can respectively correspond to the first active area AR1 and the third active area AR3 in the first state and in the second state.

In the present embodiment, the first active area AR1 and the third active area AR3 may be separated from each other. In other words, the first active area AR1 may not be connected to the third active area AR3. In such condition, a transmittance of an area located between the first active area AR1 and the third active area AR3 may be lower than the transmittance of the first active area AR1 and the transmittance of the third active area AR3. For example, in the present embodiment, the second active area AR2 and/or the active area AR4 may be located between the first active area AR1 and the third active area AR3. In some embodiments, the first active area AR1 and the third active area AR3 may be connected to each other.

Although it is not shown in the figure, the electronic panel EP may further include a buffer area adjacent to the first active area AR1 and the third active area AR3. In some embodiments, the buffer area may be located between the first active area AR1 and the third active area AR3 and connect the first active area AR1 and the third active area AR3. In some embodiments, the buffer area, the first active area AR1 and the third active area AR3 of the electronic panel EP may form a strip-shaped area extending along the unfolded-folded direction ST. The transmittance of the buffer area may be greater than the transmittances of the second active area and/or the active area AR4 but lower than the transmittances of the first active area AR1 and/or the third active area AR3. Through the design of the buffer area, the influence of process tolerance of the electronic device ED on the light receiving effect of the optical module OM may be reduced.

In the present embodiment, the first active area AR1 is separated from the third active area AR3 by a distance D1. Specifically, the distance D1 may be defined as the minimum distance between the first active area AR1 and the third active area AR3 in the unfolded-folded direction ST (for example, the direction X). It should be noted that the distance D1 may be measured in the state that the first active area A1 and the third active area AR3 are flattened. For example, the distance D1 may be measured in the second state (as shown in the state (II) in FIG. 1) of the electronic device ED, but not limited thereto. The distance D1 is also labeled in FIG. 2, wherein FIG. 2 shows the bottom view of the electronic device ED after the electronic device ED is flattened. In addition, the first active area AR1 may have a width Wa. Specifically, the width Wa may be defined as the minimum width of the first active area AR1 in the unfolded-folded direction ST, but not limited thereto. Moreover, when the electronic device ED changes from the first state to the second state, an edge of the electronic panel EP may be configured to move along the unfolded-folded direction ST by a distance S1. Specifically, as shown in FIG. 1, the edge E1 of the electronic panel EP may be located at a position PS1 in the first state of the electronic device ED and located at a position PS2 in the second state of the electronic device ED, and the distance S1 may be defined as the distance between the position PS1 and the position PS2 in the unfolded-folded direction ST (or the direction X). The edge E1 of the electronic panel EP mentioned above may be the edge of the first portion P1. According to the present embodiment, the distance D1, the width Wa and the distance S1 may satisfy the following formula (1):

$$D 1 = S 1 - Wa \qquad ( 1 )$$

Through the above-mentioned design, the optical module OM may be assisted to correspond to the first active area AR1 and the third active area AR3 respectively in the first state and in the second state of the electronic device ED. That is, the distance D1 between the first active area AR1 and the third active area AR3 may be determined according to the moving distance S1 of the edge E1 of the electronic panel EP when the electronic device ED changes from the first state to the second state and the width Wa of the first active area AR1, thereby designing the positions of the first active area AR1 and the third active area AR3.

In addition, as shown in FIG. 1 and FIG. 2, the third active area AR3 may have a width WD. The width WD may be defined as the minimum width of the third active area AR3 in the unfolded-folded direction ST. In the present embodiment, the width WD of the third active area AR3 may be the same as the width Wa of the first active area AR1, but not limited thereto. Therefore, in the second state of the electronic device ED, a distance W1 may be included between the first active area AR1 and the edge E1 of the electronic panel EP in the unfolded-folded direction ST, and a distance W2 may be included between the third active area AR3 and the position PS1 at which the edge E1 of the electronic panel EP is located when the electronic device ED is in the first state (or the folding state) in the unfolded-folded direction ST, wherein the distance W1 may be the same as the distance W2. The width W1 mentioned above may also be regarded as the distance between the first active area AR1 and the edge E1 of the electronic panel EP in the first state of the electronic device ED. The distance W1 and the distance W2 mentioned above may be measured in the state that the first active area AR1 and the third active area AR3 are flattened.

In some embodiments, the width WD of the third active area AR3 may be greater than the width Wa of the first active area Wa. In such condition, the distance W1 and the distance W2 mentioned above may be different. For example, the distance W2 may be lower than the distance W1. In such condition, the distance D1, the width Wa and the distance S1 may satisfy the following formula (2):

$$S 1 - Wa - W 1 + W 2 \leq D 1 < S 1 - Wa \qquad ( 2 )$$

By making the width WD of the third active area AR3 greater than or equal to the width Wa of the first active area AR1, the possibility that the optical module OM is not corresponding to the third active area AR3 when the electronic device ED is in the second state may be reduced.

According to the present embodiment, as shown in FIG. 2, the supporting plate SUP of the electronic device ED may include a first opening O1 overlapped with the first active area AR1 and a plurality of second openings O2 overlapped with the second portion P2. Specifically, in the normal direction of the electronic device ED, the range of the first active area AR1 may be located in the disposition range of the first opening O1. In some embodiments, the range of the first active area AR1 may coincide with the disposition range of the first opening O1, as shown in FIG. 2. At this time, the range of the first active area AR1 may be defined through the first opening O1, but not limited thereto. In some embodiments, the disposition range of the first opening O1 may be greater than the range of the first active area AR1. In such condition, the size (such as the width, the length or the area, but not limited thereto) of the first opening O1 may be greater than or equal to the size of the first active area AR1. The first opening O1 may be formed by removing at least a portion of the supporting plate SUP corresponding to the first active area AR1, and the second openings O2 may be formed by removing at least a portion of the supporting plate SUP corresponding to the second portion P2. The first opening O1 may have an area A1, and one of the second openings O2 may have an area A2, wherein the area A1 may be greater than the area A2. The area A1 (or the area A2) may be the area of the first opening O1 (or the second opening O2) in the top view of the electronic device ED. It should be noted that although the boundary between the first portion P1 and the second portion P2 in FIG. 1 is aligned with the edge of the second opening O2 closest to the first portion P1, the present disclosure is not limited thereto. In some embodiments, as shown in FIG. 2, the boundary between the first portion P1 and the second portion P2 may not be aligned with the edge of the second opening O2.

In addition, the supporting plate SUP of the electronic device ED may further include a third opening O3 overlapping the third active area AR3, wherein the third opening O3 may be formed by removing at least a portion of the supporting plate SUP corresponding to the third active area AR3. The third opening O3 may be overlapped with the second portion P2. The third opening O3 may have an area A3, wherein the area A3 may be greater than the area A2 of one of the second openings O2. In the normal direction of the electronic device ED, the range of the third active area AR3 may be located in the disposition range of the third opening O3. In such condition, the range of the third active area AR3 may be defined through the third opening O3, but not limited thereto. In the present embodiment, the first active area AR1 and the third active area AR3 may be separated from each other, and the third opening O3 corresponding to the third active area AR3 and the first opening O1 corresponding to the first active area AR1 may be separated from each other, but not limited thereto. “The first opening O1 and the third opening O3 are separated from each other” described herein may represent that the material of the supporting plate SUP may be included between the first opening O1 and the third opening O3. When the user unfolds (or expands) the electronic device ED, the supporting plate SUP may move together with the electronic panel EP. Therefore, the corresponding relationship between the first active area AR1 and the first opening O1 (or the corresponding relationship between the third active area AR3 and the third opening O3) does not change as the state of the electronic device ED changes.

According to the present embodiment, when the electronic device ED is in the first state, the optical module OM may correspond to the first active area AR1, and the first opening O1 of the supporting plate SUP may overlap the optical module OM; and when the electronic device ED is in the second state, the optical module OM may correspond to the third active area AR3, and the third opening O3 of the supporting plate SUP may overlap the optical module OM. In other words, the optical module OM may correspond to the opening of the supporting plate SUP when the electronic device ED is in the first state or in the second state. Therefore, the influence of the supporting plate SUP on the light receiving effect of the optical module OM may be reduced. In the first state of the electronic device ED, the disposition range of the first opening O1 may cover the disposition range of the optical module OM; and in the second state of the electronic device ED, the disposition range of the third opening O3 may cover the disposition range of the optical module OM. In addition, by disposing the plurality of second openings O2 at the portion of the supporting plate SUP corresponding to the second portion P2, the flexibility of the second portion P2 may be improved, thereby reducing the possibility of damage to the electronic device ED in the folding/unfolding process of the electronic device ED. It should be noted that the shapes, the sizes and the arrangements of the first opening O1, the second opening O2 and the third opening O3 are exemplary, and the present disclosure is not limited thereto.

It should be noted that the structure of the electronic device ED of the present disclosure is not limited to the contents mentioned above or what is shown in FIG. 1, and other suitable elements or layers may be included in the electronic device ED. In addition, the stacking condition or the disposition condition of the elements or the layers in the electronic device ED are not limited to the structure shown in FIG. 1.

The operating process of the electronic device ED of the present embodiment will be described in the following.

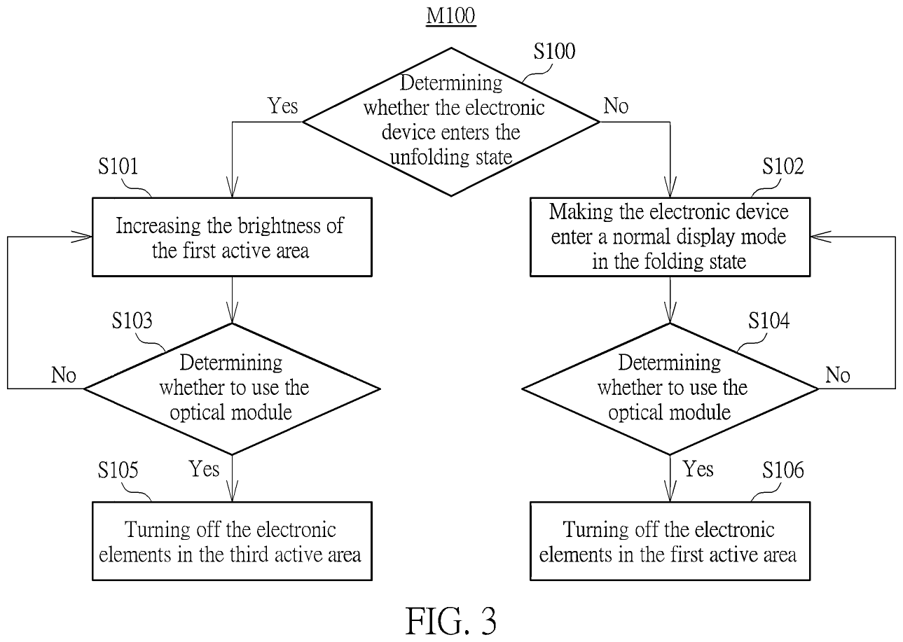

Referring to FIG. 3, FIG. 3 schematically illustrates an operating process of the electronic device according to the first embodiment of the present disclosure. The electronic device ED of the present embodiment may for example be operated by an operating process M100, but not limited thereto. According to the present embodiment, the operating process M100 may include a step S100: determining whether the electronic device enters the unfolding state. Specifically, when the electronic device ED is in the folding state (or the first state), it can be determined whether the electronic device ED enters the unfolding state according to the user's operation. When the user does not stretch the electronic device ED, it is determined that the electronic device ED does not enter the unfolding state, and when the user stretch the electronic device ED, it is determined that the electronic device ED enters the unfolding state.

When it is determined that the electronic device ED does not enter the unfolding state, the operating process M100 may include a step S102: making the electronic device ED enter a normal display mode in the folding state. Specifically, the electronic device ED may perform the function of displaying pictures or images in the folding state, and in such condition, the electronic elements EL (such as the light emitting units LU shown in FIG. 12) of the electronic panel EP corresponding to the first portion P1 may emit light to display images, and the electronic elements EL of the electronic panel EP corresponding to the second portion P2 may be turned-off or may not be operated. When the electronic device ED is in the first state, the operating process M100 may further include a step S104: determining whether to use the optical module OM. For example, it can be determined that whether the electronic device ED enters a camera mode, but not limited thereto. When the optical module OM is determined to be used, the portion of the electronic elements EL (such as the light emitting units LU) of the electronic panel EP corresponding to the optical module OM may be turned off. Since the optical module OM is corresponding to the first active area AR1 when the electronic device ED is in the first state, when it is determined to use the optical module OM, the operating process M100 may further include a step S106: turning off the electronic elements EL in the first active area AR1. Therefore, the influence of the electronic elements EL on the optical module OM may be reduced. When it is determined that the user does not use the optical module OM, the display mode mentioned in the step S102 may be maintained.

In another aspect, when the electronic device ED is determined to enter the unfolding state, the operating process M100 may include a step S101: increasing the brightness of the first active area AR1. Specifically, when the electronic device ED is unfolded, the optical module OM may not overlap the first active area AR1. In such condition, the brightness of the first active area AR1 may be increased to improve the display effect of the electronic device ED. For example, the brightness difference between the first active area AR1 and other active areas (such as the second active area AR2 and/or the active area AR4) may be reduced by increasing the brightness of the electronic elements EL (such as the light emitting units LU) in the first active area AR1, such that the image displayed in the first portion P1 may be more uniform. When the electronic device ED is unfolded and in the second state, the operating process M100 may further include a step S103: determining whether to use the optical module OM. When the optical module OM is determined to be used, the operating process M100 may further include a step S105: turning off the portion of the electronic elements EL (such as the light emitting units LU) of the electronic panel EP corresponding to the optical module OM, that is, turning off the electronic elements EL (such as the light emitting units LU) in the third active area AR3. When it is determined that the user does not use the optical module OM, the display mode mentioned in the step S103 may be maintained. When the electronic device ED is unfolded and in the second state, the electronic elements EL (such as the light emitting units LU shown in FIG. 12) of the electronic panel EP corresponding to the second portion P2 may emit light to display images.

It should be noted that the operating process of the electronic device ED of the present embodiment is not limited to the operating process M100 mentioned above, which may further include other suitable steps.

Other embodiments of the present disclosure will be described in the following. In order to simplify the description, the same elements or layers in the following embodiments would be labeled with the same symbol, and the features thereof will not be redundantly described. The differences between the embodiments will be detailed in the following.

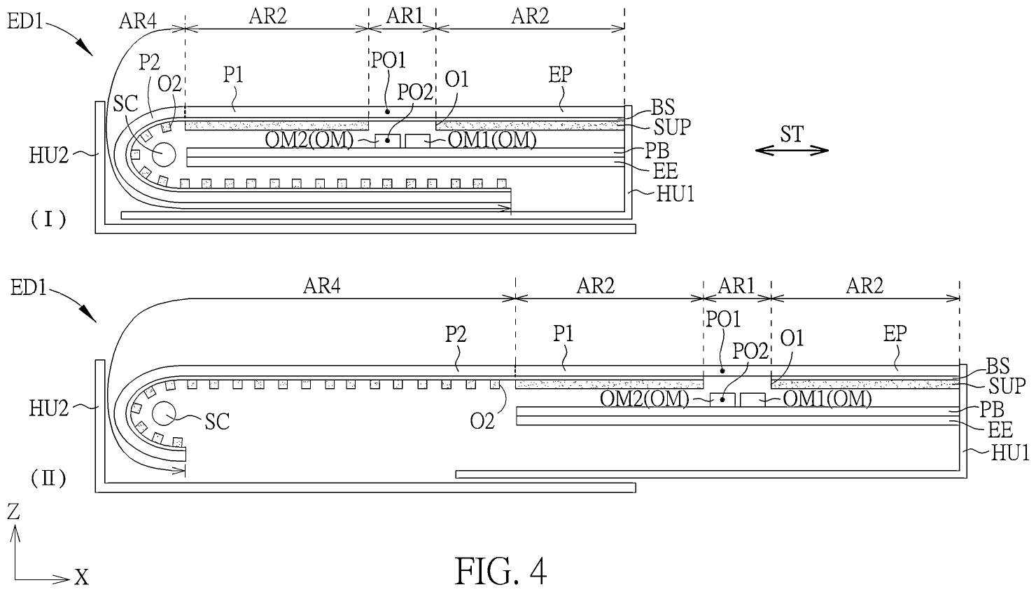

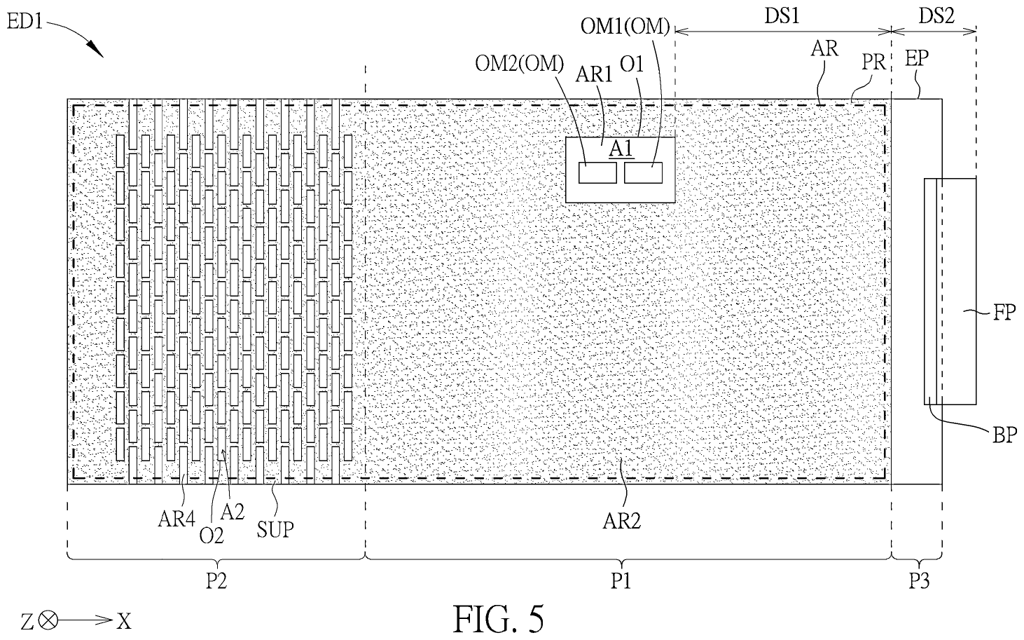

Referring to FIG. 4 and FIG. 5, FIG. 4 schematically illustrates a cross-sectional view of an electronic device according to a second embodiment of the present disclosure, and FIG. 5 schematically illustrates a bottom view of the electronic device according to the second embodiment of the present disclosure. Specifically, FIG. 5 shows the bottom view of the electronic device ED1 after the electronic device ED1 is flattened. In order to simply the figure, the peripheral area PR in the first portion P1 and the second portion P2 is omitted in FIG. 4. According to the present embodiment, when the electronic device ED1 changes from the first state (as shown in the state (I) in FIG. 4) to the second state (as shown in the state (II) in FIG. 4), the electronic panel EP and the optical module OM may be configured to move together. “The electronic panel EP and the optical module OM are configured to move together” described herein may represent that the degree of movement of the electronic panel EP and the optical module OM may be the same, or the displacement of the electronic panel EP may be the same as the displacement of the optical module OM during the unfolding process of the electronic device ED, and the relative position between the electronic panel EP and the optical module OM would not change. In such condition, when the electronic device ED1 is in the folding state (that is, the first state), a point PO1 may be defined in the electronic panel EP, and a point PO2 may be defined in the optical module OM, wherein the point PO1 may correspond to the point PO2. After that, when the electronic device ED1 is in the unfolding state (as shown in the state (II)), the point PO1 in the electronic panel EP may still correspond to the point PO2 in the optical module OM.

According to the present embodiment, the optical module OM may correspond to the first active area AR1 of the first portion P1 when the electronic device ED1 is in the first state. In addition, as mentioned above, since the electronic panel EP and the optical module OM of the electronic device ED1 may be configured to move together, the optical module OM may still correspond to the first active area AR1 when the electronic device ED1 changes from the first state to the second state. In other words, when the electronic device ED1 is switched between the first state and the second state, the optical module OM would not be deviated from the first active area AR1. Therefore, compared with the electronic device ED mentioned above, the second portion P2 of the electronic panel EP of the electronic device ED1 of the present embodiment may not include the third active area AR3 mentioned above, but include the active area AR4 mentioned above, wherein the transmittance of the active area AR4 may be the same as the transmittance of the second active area AR2 of the first portion P1, but not limited thereto.

In addition, the supporting plate SUP of the electronic device ED1 may include the first opening O1 corresponding to the first active area AR1 and the plurality of second openings O2 corresponding to the second portion P2, wherein the optical module OM may correspond to the first opening O1 of the supporting plate SUP in the first state and in the second state of the electronic device ED1. Compared with the electronic device ED mentioned above, the supporting plate SUP of the electronic device ED1 of the present embodiment may not include the third opening O3 mentioned above. The features of the first opening O1 and the second openings O2 may refer to the contents mentioned above, and will not be redundantly described.

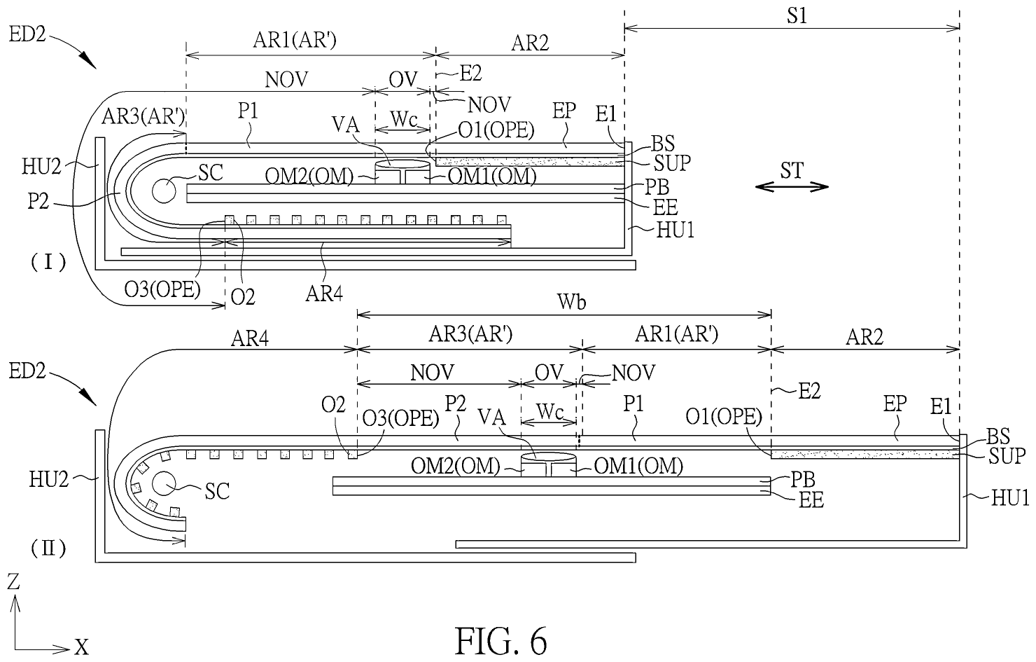

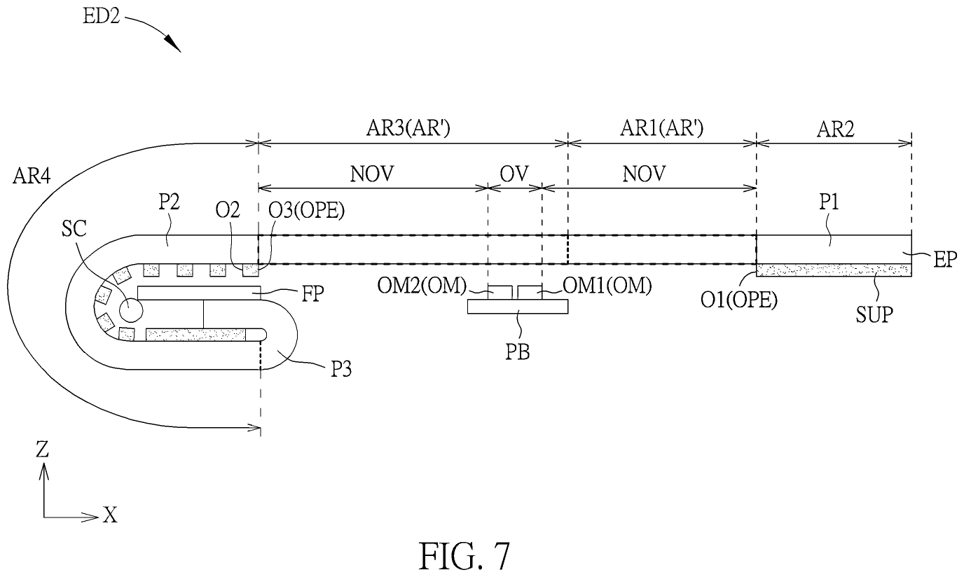

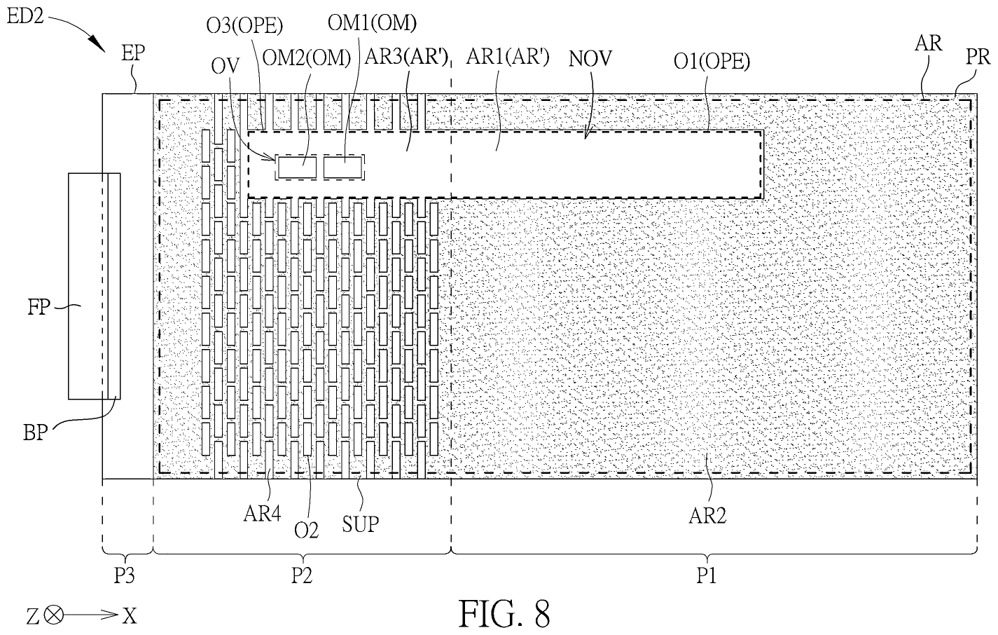

Referring to FIG. 6 to FIG. 8, FIG. 6 and FIG. 7 schematically illustrate cross-sectional views of an electronic device according to a third embodiment of the present disclosure, and FIG. 8 schematically illustrates a bottom view of the electronic device according to the third embodiment of the present disclosure. The state (I) in FIG. 6 may be the first state of the electronic device ED2, and the state (II) in FIG. 6 may be the second state of the electronic device ED2. In order to simplify the figure, the peripheral area PR in the first portion P1 and the second portion P2 is omitted in FIG. 6 and FIG. 7. According to the present embodiment, the first portion P1 of the electronic panel EP of the electronic device ED2 may include the first active area AR1, and the second portion P2 of the electronic panel EP of the electronic device ED2 may include the third active area AR3, wherein the first active area AR1 may be connected to the third active area AR3. Specifically, the first active area AR1 and the third active area AR3 may extend to the boundary of the first portion P1 and the second portion P2 and be connected to each other. In such condition, the first active area AR1 and the third active area AR3 may be combined to form an active area AR′, wherein the active area AR′ may be the portion of the active area AR having a greater transmittance. That is, the active area AR′ has a greater transmittance than other areas in the active area AR (for example, the second active area AR2 and/or the active area AR4). As shown in FIG. 8, in the top view of the electronic device ED2, the active area AR′ formed by combining the first active area AR1 and the third active area AR3 may be a strip-shaped area extending along the unfolded-folded direction ST, but not limited thereto.

According to the present embodiment, in the top view of the electronic device ED2, the optical module OM of the electronic device ED2 may overlap the active area AR′ when the electronic device ED2 is in the first state and in the second state. Specifically, as shown in FIG. 6, when the electronic device ED2 is switched between the first state and the second state, the relative position between the optical module OM and the electronic panel EP may change, but not limited thereto. In such condition, when the electronic device ED2 is in the first state, the optical module OM may correspond to the first active area AR1 in the active area AR′ (as shown in the state (I)); and when the electronic device ED2 is in the second state, the optical module OM may for example move along the direction −X relative to the active area AR′ and may correspond to the third active area AR3 in the active area′ (as shown in the state (II)), but not limited thereto. For example, the optical module OM may correspond to the edge E2 of the first active area AR1 when the electronic device ED2 is in the first state, such that the optical module OM may move under the condition that the optical module OM corresponds to the active area AR′ when the electronic device ED2 is unfolded, but not limited thereto. In some embodiments, the relative position between the optical module OM and the electronic panel EP may not change when the electronic device ED2 is switched between the first state and the second state (that is, the optical module OM and the electronic panel EP may move together), and the optical module OM may correspond to the same portion (for example, the first active area AR1, but not limited thereto) of the active area AR′ whether the electronic device ED2 is in the first state or in the second state. Since the first active area AR1 and the third active area AR3 are connected to each other to form a strip-shaped area extending along the unfolded-folded direction ST, the optical module OM may continuously correspond to the active area AR′ during the process in which the electronic device ED2 changes from the first state to the second state. In such condition, the functions of the optical module OM may be performed in any state during the process in which the electronic device ED2 is unfolded from the first state to the second state, but not limited thereto.

As shown in FIG. 8, the sum of the widths of the first active area AR1 and the third active area AR3 of the electronic device ED2 may be a width Wb. Specifically, the width Wb may be the sum of the widths of the first active area AR1 and the third active area AR3 in the unfolded-folded direction ST, or the width Wb may be the width of the active area AR′ in the unfolded-folded direction ST. In addition, when the electronic device ED2 changes from the first state to the second state, the edge of the electronic panel EP may be configured to move along the unfolded-folded direction ST by a distance S1. The definition of the distance S1 may refer to the contents mentioned above, and will not be redundantly described. Moreover, in the present embodiment, the optical module OM may have an aperture VA, wherein the aperture VA may have a width Wc. “The aperture VA of the optical module OM” described herein may be the aperture in the optical module OM for receiving the light, such as the aperture of the camera, but not limited thereto. The width Wc of the aperture VA may be defined as the maximum width of the aperture VA in the unfolded-folded direction ST, but not limited thereto. In some embodiments, when the electronic device ED2 includes an optical module OM, the width Wc may be the width of the aperture VA of the optical module OM. In some embodiments, when the electronic device ED2 includes a plurality of optical modules OM, the apertures of the plurality of optical modules OM may form an aperture structure, and the width Wc may be the maximum width of the aperture structure in the unfolded-folded direction ST, wherein the range of the aperture structure may for example be defined through an area enclosed by the outer edges of the outermost apertures VA among the plurality of apertures VA. It should be noted that the aperture VA of the optical module OM shown in FIG. 6 is exemplary, which does not represent the real structure of the aperture VA. According to the present embodiment, the width Wb, the distance S1 and the width Wc may satisfy the following formula (3):

$$Wb \geq S 1 + Wc \qquad ( 3 )$$

Through the above-mentioned design, the optical module OM may be assisted to continuously correspond to the active area AR′ during the process in which the electronic device ED2 changes from the first state to the second state.

In addition, according to the formula (3) above, the width Wb and the distance S1 may satisfy the following formula (4):

$$Wb \geq S 1 \qquad ( 4 )$$

That is, the width Wb of the active area AR′ may be greater than or equal to the moving distance S1 of the edge of the electronic panel EP when the electronic device ED2 changes from the first state to the second state. Therefore, the possibility that the optical module OM does not correspond to the active area AR′ when the electronic device ED2 is in the first state or in the second state may be reduced.

According to the present embodiment, the supporting plate SUP of the electronic device ED2 may include the first opening O1 overlapping the first active area AR1, a plurality of second openings O2 overlapping the second portion P2 and the third opening O3 overlapping the third active area AR3. Since the first active area AR1 is connected to the third active area AR3, the third opening O3 may be connected to the first opening O1. Specifically, the first opening O1 and the third opening O3 may be combined to form an opening OPE, and the opening OPE may overlap the active area AR′. The optical module OM may continuously correspond to the opening OPE during the process in which the electronic device ED2 changes from the first state to the second state. Therefore, the light receiving effect of the optical module OM may be improved. In the normal direction of the electronic device ED2, the range of the active area AR′ may be located in the disposition range of the opening OPE. Specifically, the opening OPE may have a length L1 in the unfolded-folded direction ST, wherein the length L1 may be greater than or equal to the width Wb of the active area AR′. In such condition, according to the formula (4) above, the length L1 and the distance S1 may satisfy the following formula (5):

$$L 1 \geq S 1 \qquad ( 5 )$$

That is, the length L1 of the opening OPE in the unfolded-folded direction ST may be greater than or equal to the moving distance S1 of the edge of the electronic panel EP when the electronic device ED2 changes from the first state to the second state. Through the above-mentioned design, the possibility that the optical module OM does not correspond to the opening OPE when the electronic device ED2 is switched between the first state and the second state may be reduced. The feature of the second opening OP2 may refer to the contents mentioned above, and will not be redundantly described. In the present embodiment, the area of the opening OPE may be greater than the area (that is, the area A2 mentioned above) of one of the second openings O2.

The operating process of the electronic device ED2 of the present embodiment will be detailed in the following.

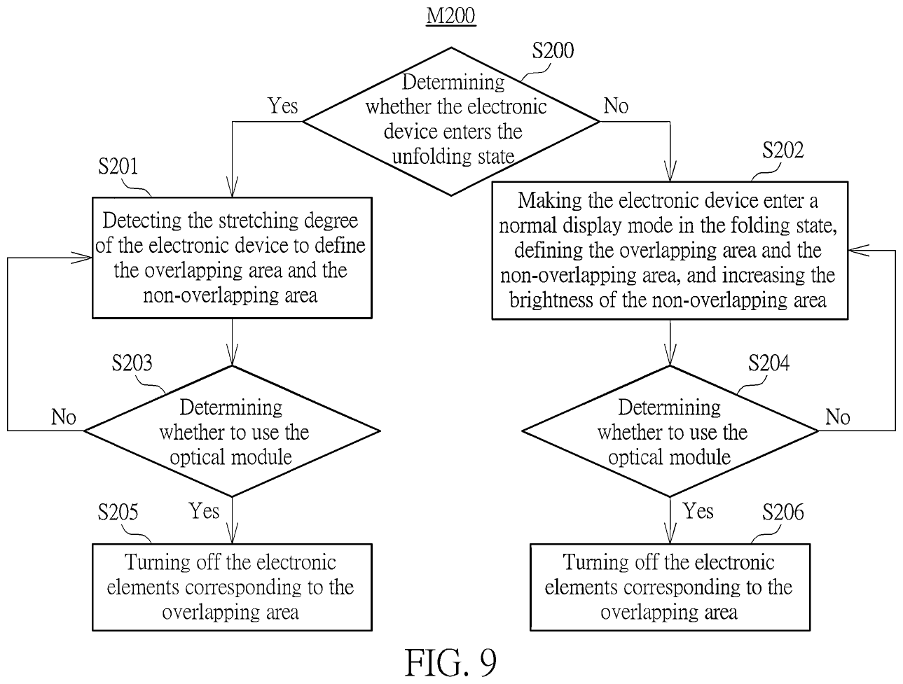

Referring to FIG. 9, FIG. 9 schematically illustrates an operating process of the electronic device according to the third embodiment of the present disclosure. The electronic device ED2 of the present embodiment may for example be operated by an operating process M200, but not limited thereto. According to the present embodiment, the operating process M200 may include a step S200: determining whether the electronic device enters the unfolding state. Specifically, when the user does not stretch the electronic device ED2, it is determined that the electronic device ED2 does not enter the unfolding state, and when the user stretch the electronic device ED2, it is determined that the electronic device ED2 enters the unfolding state.

When it is determined that the electronic device ED2 does not enter the unfolding state, the operating process M200 may include a step S202: making the electronic device ED2 enter a normal display mode in the folding state. Specifically, the electronic device ED2 may perform the function of displaying pictures or images in the folding state. According to the present embodiment, when the electronic device ED2 is in the folding state, an overlapping area OV and a non-overlapping area NOV may be defined in the active area AR′ according to the position of the optical module OM. The overlapping area OV may be defined as the area in the active area AR′ corresponding to the optical module OM, and other areas in the active area AR′ except the overlapping area OV may be defined as the non-overlapping area NOV. Specifically, when the electronic device ED2 includes an optical module OM, the overlapping area OV may correspond to the area enclosed by the outer edge of the optical module OM; and when the electronic device ED2 includes a plurality of optical modules OM, the overlapping area OV may correspond to the area enclosed by the outer edges of the outermost optical modules OM among the plurality of optical modules OM. In other words, the overlapping area OV is the portion of the active area AR′ overlapping the optical module OM. After the overlapping area OV and the non-overlapping area NOV are defined, the step S202 may further include increasing the brightness of the non-overlapping area NOV, such that the display effect of the electronic device ED2 may be improved. For example, the brightness difference between the non-overlapping area NOV and other active areas (such as the second active area AR2 and/or the active area AR4) may be reduced by increasing the brightness of the electronic elements EL (such as the light emitting units LU) in the non-overlapping area NOV. When the electronic device ED2 is in the first state, the operating process M200 may further include a step S204: determining whether to use the optical module OM (for example, it can be determined that whether the electronic device ED2 enters a camera mode, but not limited thereto). When the optical module OM is determined to be used, since the optical module OM corresponds to the overlapping area OV, a step S206 may be performed to turn off the electronic elements EL (such as the light emitting units LU) corresponding to the overlapping area OV, such that the influence of the electronic elements EL on the light receiving effect of the optical module OM may be reduced. When it is determined that the user does not use the optical module OM, the display mode mentioned in the step S202 may be maintained.

In another aspect, when the electronic device ED2 is determined to enter the unfolding state, the electronic device ED2 may display images in the unfolding state. In such condition, the operating process M200 may include a step S201: detecting the stretching degree of the electronic device ED2 to define the overlapping area OV and the non-overlapping area NOV. Specifically, when the electronic device ED2 is unfolded, the relative position between the optical module OM and the electronic panel EP may change, such that the optical module OM is deviated from the overlapping area OV defined when the electronic device ED2 is in the folding state. In such condition, the stretching degree of the electronic device ED2 may be detected, and the overlapping area OV and the non-overlapping area NOV in the active area AR′ may be redefined. The overlapping area OV defined when the electronic device ED2 is in the folding state and the overlapping area OV defined when the electronic device ED2 is in the unfolding state may be different areas in the active area AR′. For example, as shown in FIG. 6, when the electronic device ED2 is unfolded from the folding state (that is, the first state, as shown in the state (I)) to the unfolding state (such as the second state, as shown in the state (II)), the position of the overlapping area OV in the active area AR′ may change. FIG. 7 and FIG. 8 also show the definition of the overlapping area OV and the non-overlapping area NOV according to the position of the optical module OM. After the overlapping area OV and the non-overlapping area NOV are redefined according to the stretching degree of the electronic device ED2, the brightness of the non-overlapping area NOV may be increased to improve the display effect of the electronic device ED2. “Detecting the stretching degree of the electronic device” mentioned above may for example be performed by disposing a sensor at the housing HU1 or through other suitable ways. When the electronic device ED2 is in the unfolding state, the operating process of the electronic device ED2 may further include a step S203: determining whether to use the optical module OM. When the optical module OM is determined to be used, a step S205: turning off the portion of the electronic elements EL (such as the light emitting units LU) corresponding to the overlapping area OV may be performed. When it is determined that the user does not use the optical module OM, the display mode mentioned in the step S203 may be maintained.

It should be noted that the operating process of the electronic device ED2 of the present embodiment is not limited to the operating process M200 mentioned above, which may include other suitable steps.

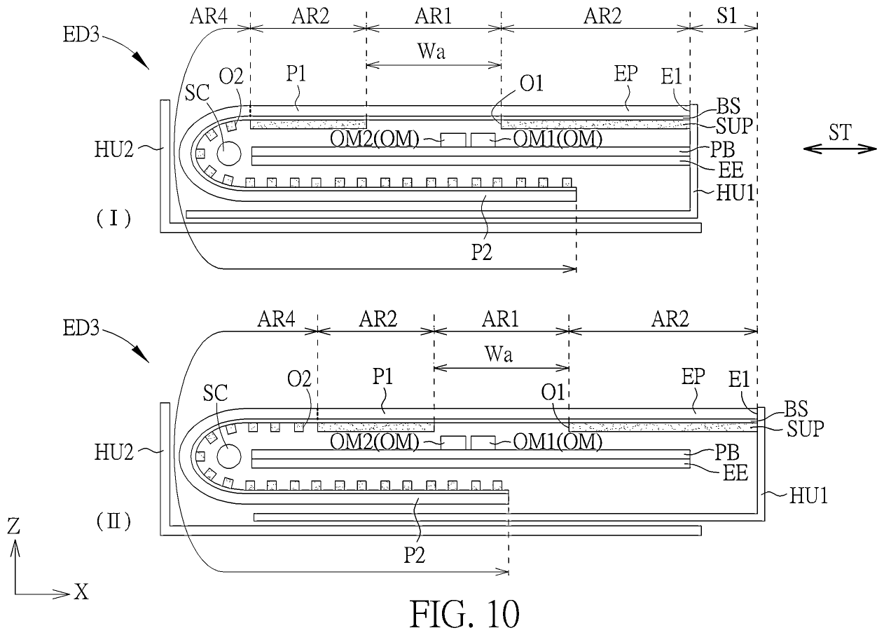

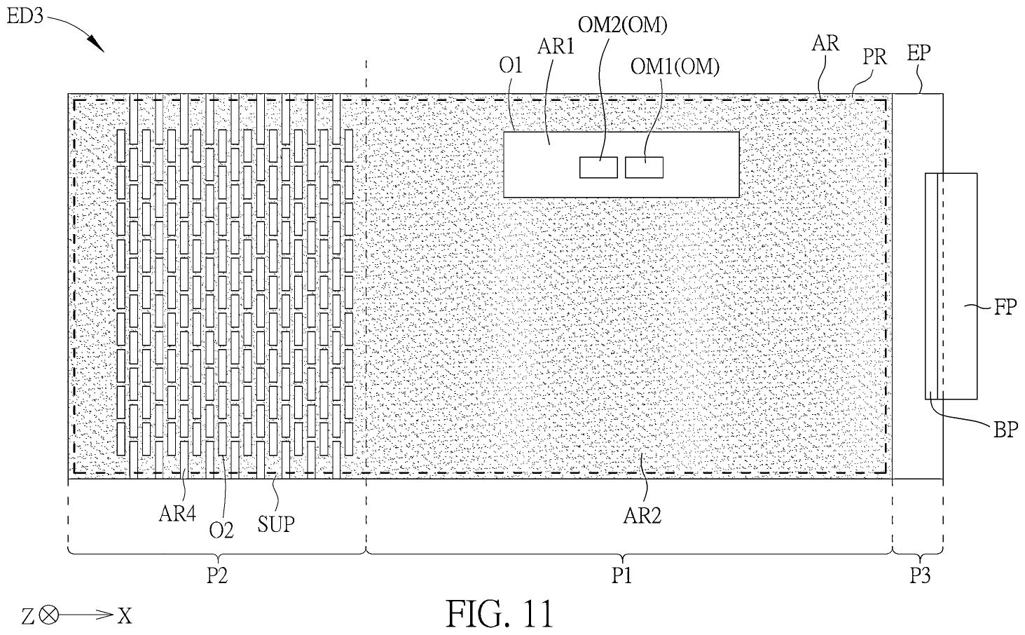

Referring to FIG. 10 and FIG. 11, FIG. 10 schematically illustrates a cross-sectional view of an electronic device according to a fourth embodiment of the present disclosure, and FIG. 11 schematically illustrates a bottom view of the electronic device according to the fourth embodiment of the present disclosure. In order to simplify the figure, the peripheral area PR in the first portion P1 and the second portion P2 is omitted in FIG. 10. According to the present embodiment, the first portion P1 of the electronic panel EP of the electronic device ED3 may include the first active area AR1 and the second active area AR2, wherein the optical module OM may overlap the first active area AR1 when the electronic device ED3 is in the folding state (that is, the first state) and the unfolding state (such as the second state). Specifically, the relative position between the optical module OM and the electronic panel EP may change as the electronic device ED3 is unfolded and/or folded in the present embodiment, and the optical module OM may continuously overlap the first active area AR1 during the process in which the electronic device ED3 changes from the first state to the second state. In other words, when the electronic device ED3 is switched between the first state and the second state, the optical module may move (for example, move along the unfolded-folded direction ST) in a range corresponding to the first active area AR1. In such condition, the width Wa of the first active area AR1 in the unfolded-folded direction ST may be greater than or equal to the moving distance S1 of the edge E1 of the electronic panel EP when the electronic device ED3 changes from the first state to the second state. Therefore, the possibility that the optical module OM is not corresponding to the first active area AR1 when the electronic device ED3 is in the first state or in the second state may be reduced. In addition, compared with the electronic device ED mentioned above, the electronic panel EP of the electronic device ED3 of the present embodiment may not include the third active area AR3 mentioned above. For example, the second portion P2 of the electronic panel EP of the electronic device ED3 may include the active area AR4 mentioned above, wherein the transmittance of the active area AR4 may be the same as the transmittance of the second active area AR2 of the first portion P1, but not limited thereto.

In addition, the supporting plate SUP of the electronic device ED3 may include the first opening O1 overlapping the first active area AR1 and the plurality of second openings O2 overlapping the second portion P2. Specifically, in the normal direction of the electronic device ED3, the range of the first active area AR1 may be located in the disposition range of the first opening O1. When the electronic device ED3 is switched between the first state and the second state, the optical module OM may move (for example, move along the unfolded-folded direction ST) in a range corresponding to the first opening O1, but not limited thereto. In the present embodiment, the area of the first opening O1 may be greater than the area of one of the second openings O2.

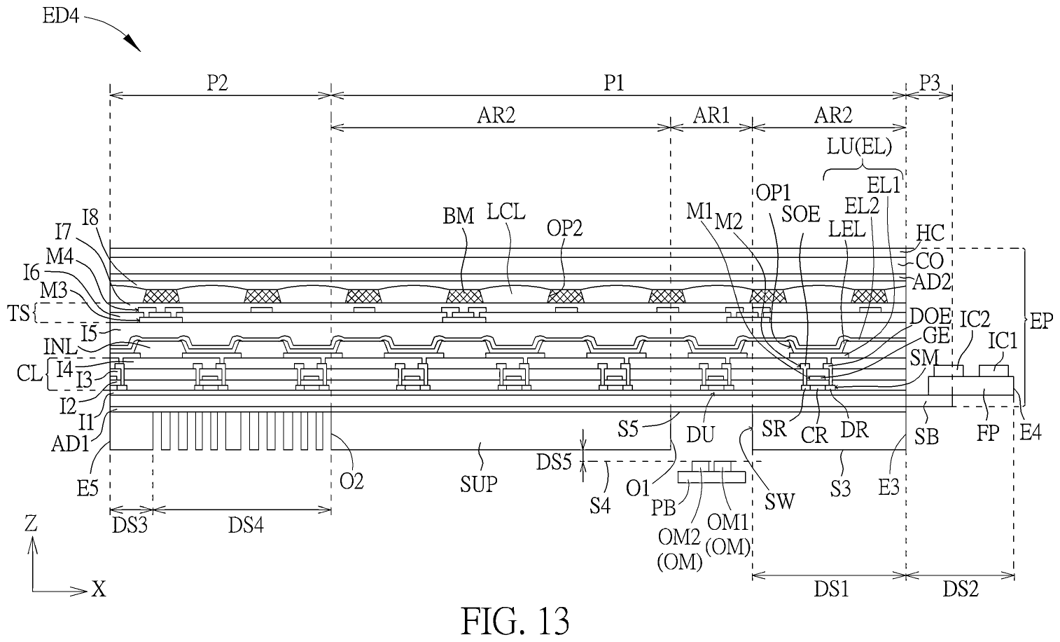

Referring to FIG. 12 and FIG. 13, FIG. 12 and FIG. 13 schematically illustrate cross-sectional views of an electronic device according to a fifth embodiment of the present disclosure. Specifically, the structure shown in FIG. 13 may be the flattened structure of the electronic device ED4 shown in FIG. 12. In order to simplify the figure, FIG. 12 and FIG. 13 just show some of the elements or the layers of the electronic device ED4, and the structure of the electronic device ED4 is not limited to what is shown in FIG. 12 and FIG. 13. In addition, the peripheral area PR is omitted in FIG. 12 and FIG. 13. According to the present embodiment, the electronic panel EP may further include a third portion P3, wherein the third portion P3 may be connected to the first portion P1. In such condition, the first portion P1 may be connected between the second portion P2 and the third portion P3. The third portion P3 may be called the bending portion of the electronic panel EP. Specifically, the third portion P3 may be defined as the portion of the electronic panel EP which is bent backward and fixed on the backside of the supporting plate SUP. For example, as shown in FIG. 12, the third portion P3 of the electronic panel EP may be fixed on a surface S3 of the supporting plate SUP opposite to the electronic panel EP. It should be noted that “the electronic panel EP is bent backward and fixed on the backside of the supporting plate SUP” mentioned above may include the embodiment that at least one of the layers of the electronic panel EP is bent backward and fixed on the backside of the supporting plate SUP. That is, the third portion P3 of the electronic panel EP may include at least one of the layers included in the electronic panel EP. In other words, the third portion P3 is not limited to include all the layers of the electronic panel EP. For example, in the present embodiment, a portion of the substrate SB of the electronic panel EP may be bent backward and fixed on the backside of the supporting plate SUP, the third portion P3 may include the portion of the substrate SB bent backward, and the third portion P3 does not include the element or the layers disposed on the portion of the substrate SB, but not limited thereto. In such condition, the third portion P3 of the electronic panel EP may be the portion of the substrate SB starts to deviate from a horizontal extending line HL2 parallel to the surface of the substrate SB.

According to the present embodiment, the electronic device ED4 may further include a flexible printed circuit board FP bonded on the third portion P3 of the electronic panel EP. Specifically, the flexible printed circuit board FP may be disposed at a side of the supporting plate SUP opposite to the electronic panel EP, that is, the backside of the supporting plate SUP. At least one electronic unit may be disposed on the flexible printed circuit board FP for controlling the electronic elements in the electronic device ED4. For example, the electronic device ED4 may further include an electronic unit IC1 and an electronic unit IC2 bonded on the flexible printed circuit board FP, wherein the electronic unit IC1 may be used to control the electronic elements EL (such as the light emitting units LU) of the electronic panel EP, and the electronic unit IC2 may be used to control the touch structure TS of the electronic panel EP, but not limited thereto. The electronic unit IC1 and the electronic unit IC2 for example include chip, other suitable electronic units or combinations thereof.

According to the present embodiment, in the normal direction of the electronic device ED4, the flexible printed circuit board FP bonded on the third portion P3 may not overlap (or not correspond to) the first active area AR1. For example, the flexible printed circuit board FP disposed at the backside of the supporting plate SUP may correspond to the second active area AR2 of the first portion P1, but not limited thereto. In some embodiments, the flexible printed circuit board FP may correspond to the peripheral area (that is, the peripheral area PR mentioned above, which is not shown in the figure) of the first portion P1. Specifically, in a horizontal direction, a distance DS1 may be included between the first opening O1 of the supporting plate SUP and the edge E3 of the supporting plate SUP, and a distance DS2 may be included between the edge E3 of the supporting plate SUP and the edge E4 of the flexible printed circuit board FP, wherein the distance DS1 may be greater than the distance DS2. In some embodiments, the distance DS1 may be the same as the distance DS2. “The horizontal direction” mentioned above may be a horizontal direction along a cross-sectional view of the electronic device ED4, which may be perpendicular to the normal direction of the supporting plate SUP. For example, the horizontal direction may be the direction X, but not limited thereto. In such condition, the distance DS1 and the distance DS2 may be measured in the condition that the electronic device ED4 is flattened. For example, as shown in FIG. 13, the distance DS1 may be the minimum distance between the first opening O1 and the edge E3 when the electronic device ED4 is flattened, and the distance DS2 may be the minimum distance between the edge E3 and the edge E4 when the electronic device ED4 is flattened. “The edge E3 of the supporting plate SUP” mentioned above may be the edge of the supporting plate SUP adjacent to the flexible printed circuit board FP. “The edge E4 of the flexible printed circuit board FP” mentioned above may be the edge of the flexible printed circuit board FP away from the electronic panel EP when the electronic device ED4 is flattened. By making the distance DS1 greater than the distance DS2, after the third portion P3 and the flexible printed circuit board FP bonded on the third portion P3 are bent backward, the flexible printed circuit board FP may not overlap the first active area AR1 corresponding to the first opening O1 in the normal direction of the electronic device ED4.

In addition, in a cross-sectional view of the electronic device ED4, a distance DS3 may be included between the second opening O2 and the edge E5 of the supporting plate SUP, and a distance DS4 may be defined through the plurality of second openings O2, wherein the distance DS4 and the distance DS1 may be greater than or equal to the distance DS3. The edge E5 of the supporting plate SUP mentioned above may be the edge of the supporting plate SUP adjacent to the second openings O2, which is opposite to the edge E3 of the supporting plate SUP. The distance DS3 may be defined as the distance between the edge E5 and the second opening O2 adjacent to the edge E5 (or the second opening O2 closest to the edge E5). The distance DS4 may be defined as the maximum distance between the edges of two second openings O2 that are farthest from each other among the plurality of second openings O2. In some embodiments, the distance DS4 may be regarded as the width of the disposition area of the plurality of second openings O2. By making the distance DS4 and the distance DS1 greater than or equal to the distance DS3, the spatial configuration of the electronic device ED4 may be improved.

The structure and disposition way of the third portion P3 of the electronic panel EP of the present embodiment may be applied to the embodiments of the present disclosure. For example, FIG. 5 shows the structure that the third portion P3 is connected to the first portion P1, and the flexible printed circuit board FP is bonded on the third portion P3 through a bonding pad BP. In addition, FIG. 5 also shows the distance DS1 and the distance DS2 mentioned above. It should be noted that in order to simplify the figure, the third portion P3 and the flexible printed circuit board FP are omitted in FIG. 4. Similarly, FIG. 11 also shows the structure that the third portion P3 is connected to the first portion P1.

According to the present embodiment, the top surface S4 of the optical module OM may not correspond to the sidewall SW of the first opening O1 in a horizontal direction (for example, the direction X). In other words, the top surface S4 of the optical module OM may not be located between the top surface of the supporting plate SUP (that is, the surface S5) and the bottom surface of the supporting plate SUP (that is, the surface S3) in the horizontal direction. In detail, the top surface S4 of the optical module OM may be lower than the surface S3 of the supporting plate SUP. It should be noted that when the electronic device ED4 includes a plurality of optical modules OM, the top surface S4 of the optical module OM may be defined as the top surface of the highest optical modules OM among the plurality of optical modules OM. Specifically, a distance DS5 may be included between the top surface S4 of the optical module OM and the surface S3 of the supporting plate SUP, wherein the distance DS5 may be greater than 0. According to the present embodiment, the distance DS5 may range from 0.01 centimeters (cm) to 1 cm (that is, 0.01 cm≤DS5≤1 cm), but not limited thereto. In some embodiments, the distance DS5 may range from 0.02 cm to 0.8 cm (0.02 cm≤DS5≤0.8 cm). In some embodiments, the distance DS5 may range from 0.03 cm to 0.6 cm (0.03 cm≤DS5≤0.6 cm). If the distance DS5 is greater than 1 cm, the light receiving effect of the optical module OM may be affected, or the entire thickness of the electronic device ED4 may be too large. If the distance DS5 is less than 0.01 cm, the optical module OM may be damaged due to electrostatic discharge (ESD). The design of disposition position of the optical module OM mentioned above may be applied to the embodiments of the present disclosure that the relative position between the optical module OM and the electronic panel EP would change during the stretching process of the electronic device, for example, the design mentioned above may be applied to the electronic device ED, the electronic device ED2 and the electronic device ED3. Specifically, by making the distance DS5 between the top surface S4 of the optical module OM and the surface S3 of the supporting plate SUP greater than 0, the possibility that the optical module OM is damaged due to collision with the supporting plate SUP during the stretching process of the electronic device ED4 may be reduced. It should be noted that in some embodiments, although it is not shown in the figure, the optical module OM may not correspond to the sidewall of the third opening O3 in the horizontal direction.

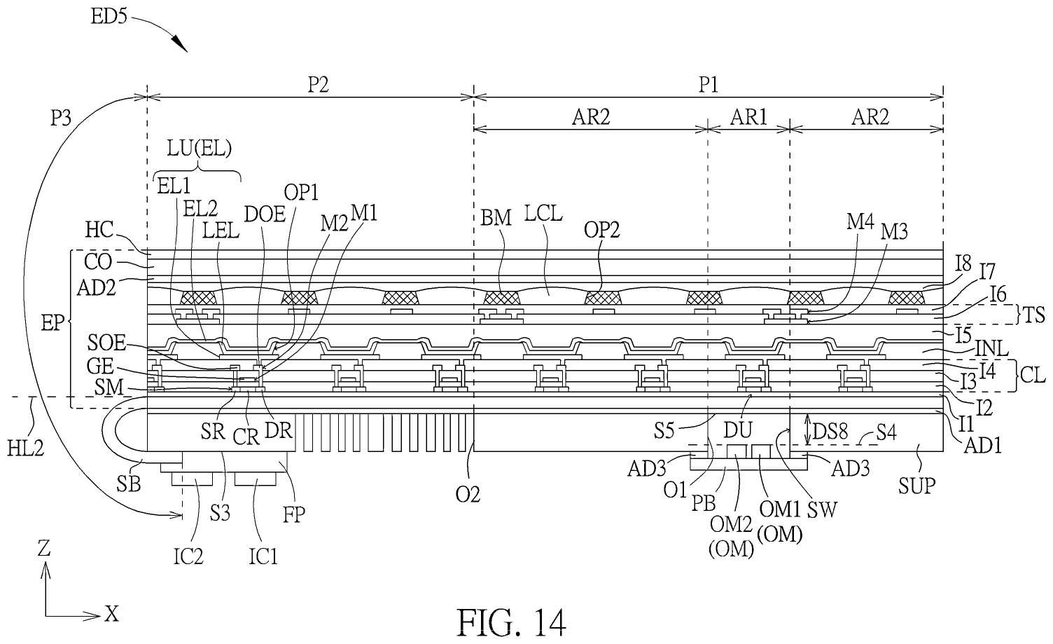

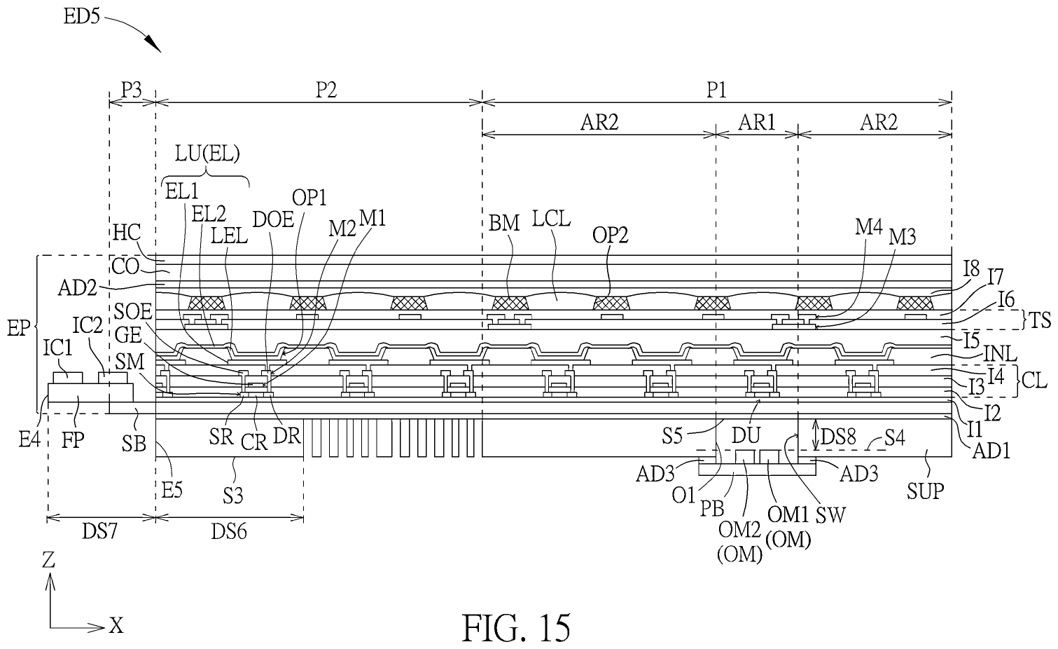

Referring to FIG. 14 and FIG. 15, FIG. 14 and FIG. 15 schematically illustrate cross-sectional views of an electronic device according to a sixth embodiment of the present disclosure. Specifically, the structure shown in FIG. 15 may be the flattened structure of the electronic device ED5 shown in FIG. 14. It should be noted that in order to simplify the figure, FIG. 14 and FIG. 15 just show some of the elements or the layers of the electronic device ED5, and the structure of the electronic device ED5 is not limited to what is shown in FIG. 14 and FIG. 15. In addition, the peripheral area PR is omitted in FIG. 14 and FIG. 15. One of the differences between the electronic device ED5 of the present embodiment and the electronic device ED4 above is the disposition position of the third portion P3. According to the present embodiment, as shown in FIG. 14, the electronic panel EP of the electronic device ED5 may include the third portion P3, wherein the third portion P3 may be connected to the second portion P2. In other words, the second portion P2 may be connected between the first portion P1 and the third portion P3. In such condition, when the third portion P3 is bent backward and fixed on the backside of the supporting plate SUP (or the side of the supporting plate SUP where the surface S3 is located), the flexible printed circuit board FP bonded on the third portion P3 may correspond to (or overlap) the second portion P2.

According to the present embodiment, in the normal direction of the electronic device ED5, the flexible printed circuit board FP bonded on the third portion P3 may not overlap (or not correspond to) the second openings O2. “The flexible printed circuit board FP does not overlap the second openings O2” mentioned above may represent that the flexible printed circuit board FP is not overlapped with any one of the second openings O2. Specifically, in the horizontal direction (for example, the direction X), a distance DS6 may be included between one of the second openings O2 of the supporting plate SUP and the edge E5 of the supporting plate SUP, and a distance DS7 may be included between the edge E5 of the supporting plate SUP and the edge E4 of the flexible printed circuit board FP, wherein the distance DS6 may be greater than the distance DS7. In some embodiments, the distance DS6 may be the same as the distance DS7. The definition of “horizontal direction” may refer to the contents mentioned above, and will not be redundantly described. In such condition, the distance DS6 and the distance DS7 may be measured in the condition that the electronic device ED5 is flattened. Specifically, the distance DS6 may be defined as the minimum distance between the one of the plurality of second openings O2 that is closest to the edge E5 and the edge E5 when the electronic device ED5 is flattened, and the distance DS7 may be the minimum distance between the edge E5 and the edge E4 when the electronic device ED5 is flattened. By making the distance DS6 greater than the distance DS7, after the third portion P3 and the flexible printed circuit board FP bonded on the third portion P3 are bent backward, the flexible printed circuit board FP may not overlap the second opening O2 in the normal direction of the electronic device ED5, such that the influence on the flexibility of the second portion P2 may be reduced.

The structure and disposition way of the third portion P3 of the electronic panel EP of the present embodiment may be applied to the embodiments of the present disclosure. For example, FIG. 2 shows the structure that the third portion P3 is connected to the second portion P2, and the flexible printed circuit board FP is bonded on the third portion P3 through a bonding pad BP. In order to simplify the figure, the third portion P3 is omitted in FIG. 1. FIG. 2 also shows the distance DS6 and the distance DS7 mentioned above. Similarly, FIG. 7 and FIG. 8 also show the structure that the third portion P3 is connected to the second portion P2. In addition, as shown in FIG. 7, in some embodiments, portions of all the layers included in the electronic panel EP may be bent backward and fixed on the backside of the supporting plate SUP. In such condition, compared with the third portion P3 mentioned above, the third portion P3 described herein may include portions of all the layers included in the electronic panel EP, but not limited thereto. In other embodiments, the layers included in the third portion P3 may be determined according to the layers in the electronic panel EP that are actually bent backward. In order to simplify the figure, the electronic panel EP is shown as a single layer in FIG. 7.

In addition, the optical module OM may be fixed on the backside of the supporting plate SUP in the present embodiment. Specifically, as shown in FIG. 14 and FIG. 15, the optical module OM may be disposed on a circuit board PB, and the circuit board PB may be attached to the surface S3 of the supporting plate SUP through an adhesive layer AD3, such that the optical module OM can be fixed, but not limited thereto. In a horizontal direction (for example, the direction X), the top surface S4 of the optical module OM may correspond to the sidewall SW of the first opening O1. In other words, in the horizontal direction, the top surface S4 of the optical module OM may be located between the top surface of the supporting plate SUP (that is, the surface S5) and the bottom surface of the supporting plate SUP (that is, the surface S3). That is, the optical module OM may at least partially be located in the first opening O1. According to the present embodiment, a distance DS8 may be included between the top surface S4 of the optical module OM and the surface S5 of the supporting plate SUP, wherein the distance DS8 may be greater than or equal to 0 micrometer (μm). Specifically, the distance DS8 may range from 1 μm to 500 μm (that is, 1 μm≤DS8≤500 μm), but not limited thereto. In some embodiments, the distance DS8 may range from 10 μm to 450 μm (that is, 10 μm≤DS8≤450 μm). In some embodiments, the distance DS8 may range from 20 μm to 400 μm (that is, 20 μm≤DS8≤400 μm). If the distance DS8 is less than 1 μm, the electronic elements EL in the electronic panel EP may be damaged due to being affected by the optical module OM. If the distance DS8 is greater than 500 μm, the possibility that the optical module OM falls off due to poor fixation of the optical module OM may increase. The design of disposition position of the optical module OM mentioned above may be applied to the embodiments of the present disclosure that the optical module OM and the electronic panel EP would move together (or the relative position between the optical module OM and the electronic panel EP would not change) during the stretching process of the electronic device, for example, the design mentioned above may be applied to the electronic device ED1.

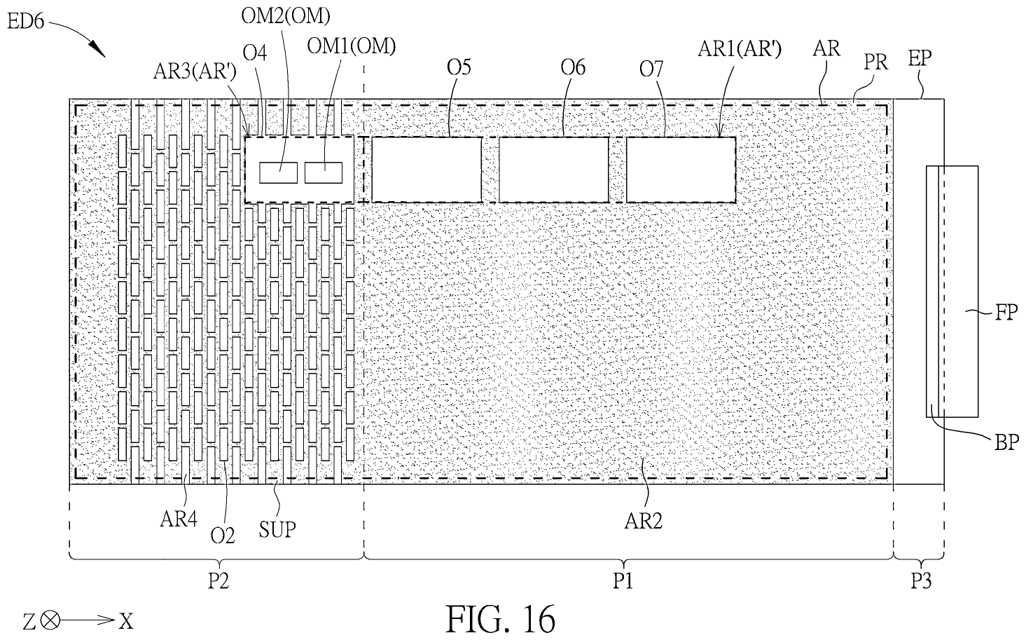

Referring to FIG. 16, FIG. 16 schematically illustrates a bottom view of an electronic device according to a seventh embodiment of the present disclosure. One of the differences between the electronic device ED6 of the present embodiment and the electronic device ED2 mentioned above is the design of the supporting plate SUP. Specifically, as shown in FIG. 16, the supporting plate SUP of the electronic device ED6 of the present embodiment may include a plurality of openings corresponding to the active area AR′, such as the opening O4, the opening O5, the opening O6 and the opening O7, wherein the plurality of openings may be separated through the supporting plate SUP, but not limited thereto. The opening O4, the opening O5, the opening O6 and the opening O7 may be arranged along the unfolded-folded direction ST. As the electronic device ED6 is unfolded to different degrees, the optical module OM may correspond to the opening O4, the opening O5, the opening O6 and the opening O7 respectively. In such condition, the optical module OM may perform its function when the optical module OM corresponds to the opening O4, the opening O5, the opening O6 and the opening O7 respectively. Through the above-mentioned design, the supporting effect of the supporting plate SUP may be improved. It should be noted that the design of openings of the supporting plate SUP described in the present embodiment may be applied to the electronic devices in the embodiments above. For example, in some embodiments, as shown in FIG. 10 and FIG. 11, the supporting plate SUP may include a plurality of openings corresponding to the first opening O1, but not limited thereto. In the electronic panel EP of the present embodiment, the third portion P3 may be connected to the first portion P1, but not limited thereto.

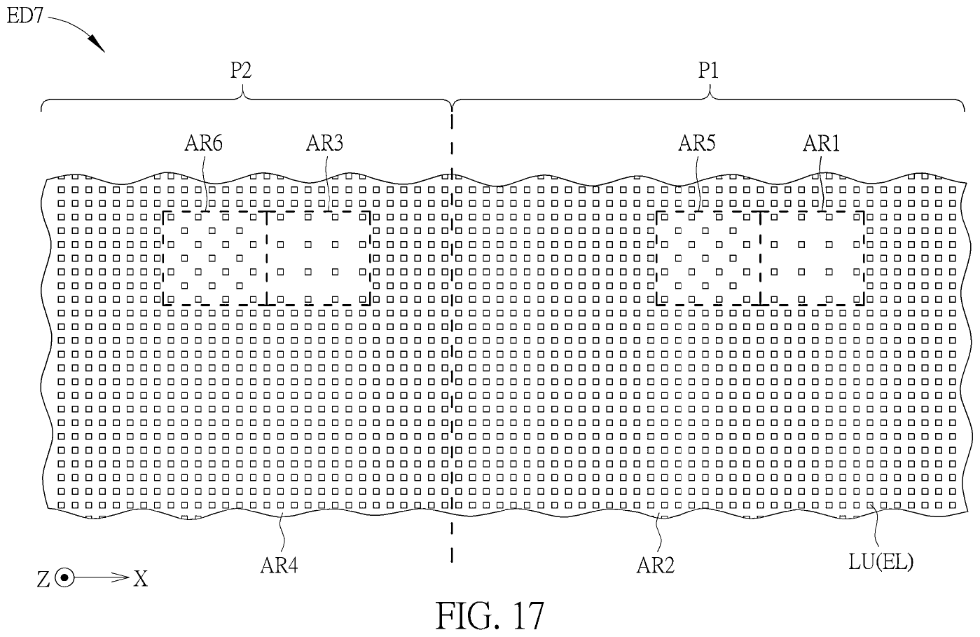

Referring to FIG. 17, FIG. 17 schematically illustrates a top view of an electronic element of an electronic device according to an eighth embodiment of the present disclosure. According to the present embodiment, the electronic panel EP of the electronic device ED7 may further include a fourth active area AR5, wherein the fourth active area AR5 may be located at the first portion P1 of the electronic panel EP. In other words, the first portion P1 may include the first active area AR1, the second active area AR2 and the fourth active area AR5. The fourth active area AR5 may be adjacent to the first active area AR1. For example, the fourth active area AR5 may be connected to the first active area AR1, but not limited thereto. According to the present embodiment, the transmittance of the fourth active area AR5 may be lower than the transmittance of the first active area AR1 and greater than the transmittance of the second active area AR2 (or the active area AR4), but not limited thereto. The transmittance difference mentioned above may for example be achieved by making the density of the electronic elements EL (such as the light emitting units LU) corresponding to the fourth active area AR5 greater than the density of the electronic elements EL corresponding to the first active area AR1 and lower than the density of the electronic elements EL corresponding to the second active area AR2, but not limited thereto.

In the present embodiment, the electronic device ED7 may for example include two optical modules (not shown in the figure, such as the optical module OM1 and the optical module OM2 mentioned above), wherein one of the two optical modules OM may overlap the first active area AR1 when the electronic device ED7 is in the first state (or the folding state), and another one of the two optical modules OM may overlap the fourth active area AR5 when the electronic device ED7 is in the first state (or the folding state). For example, when the electronic device ED7 is in the first state (or the folding state) the optical module OM1 may overlap the first active area AR1 in the normal direction of the electronic device ED7, and the optical module OM2 may overlap the fourth active area AR5 in the normal direction of the electronic device ED7. Therefore, the positions of the first active area AR1 and the fourth active area AR5 may be determined according to the positions of the optical module OM1 and the optical module OM2 when the electronic device ED7 is in the first state. In the present embodiment, the optical module OM1 corresponding to the first active area AR1 may include an optical element that has a higher demand of light transmittance than the optical module OM2 corresponding to the fourth active area AR5. For example, in the present embodiment, the optical module OM1 may include a visible light sensing element, and the optical module OM2 may include a non-visible light sensing element, such as an infrared sensing element, but not limited thereto. In some embodiments, the electronic device ED7 may include more than two optical modules OM, and the first portion P1 of the electronic panel EP may include active areas with transmittances greater than the transmittance of the second active area AR2 and respectively overlapping the optical modules OM. In addition, although it is not shown in the figure, the supporting plate of the electronic device ED7 may include opening(s) corresponding to the first active area AR1 and the fourth active area AR5. In some embodiments, the supporting plate of the electronic device ED7 may include an opening (such as the first opening O1 mentioned above), wherein the opening may overlap both the first active area AR1 and the fourth active area AR5. In some embodiments, the supporting plate of the electronic device ED7 may include two openings respectively overlapping the first active area AR1 and the fourth active area AR5.

As shown in FIG. 17, the electronic panel EP of the present embodiment may further include an active area AR6 located at the second portion P2, wherein the transmittance of the active area AR6 may be lower than the transmittance of the third active area AR3 and greater than the transmittance of the active area AR4 (or the second active area AR2), but not limited thereto. When the electronic device ED7 is in the second state (or the unfolding state), the optical module OM1 may overlap the third active area AR3 in the normal direction of the electronic device ED7, and the optical module OM2 may overlap the active area AR6 in the normal direction of the electronic device ED7. In some embodiments, the supporting plate of the electronic device ED7 may include an opening (such as the third opening O3 mentioned above) overlapping the third active area AR3 and the active area AR6. In some embodiments, the supporting plate of the electronic device ED7 may include two openings respectively overlapping the third active area AR3 and the active area AR6.

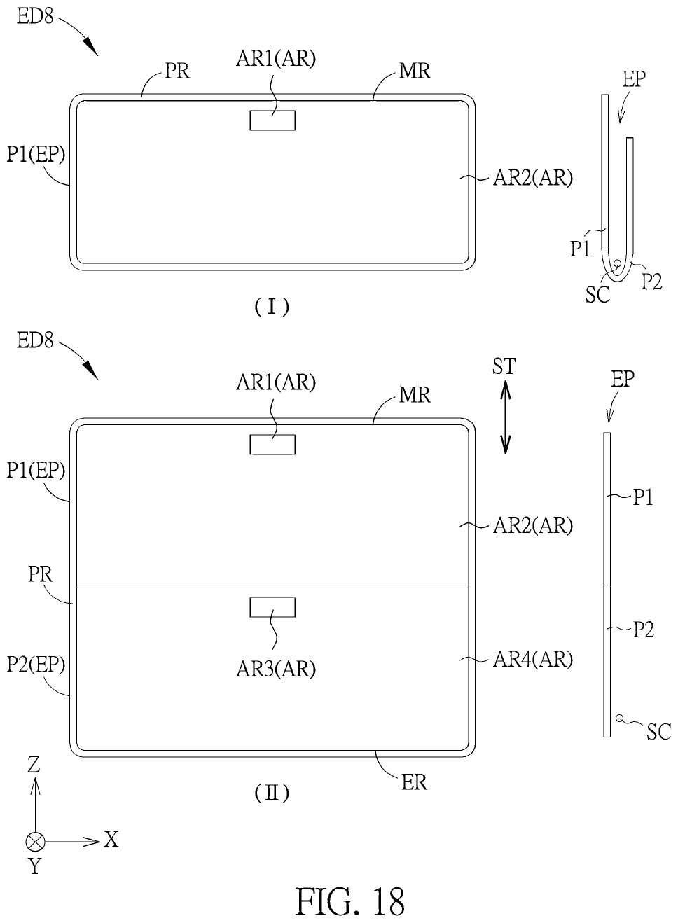

Referring to FIG. 18, FIG. 18 schematically illustrates an electronic device according to a ninth embodiment of the present disclosure. The electronic device ED8 of the present embodiment may for example include a vehicle display, but not limited thereto. For example, the electronic device ED8 may be upright, and the normal direction of the electronic device ED8 may be parallel to the direction Y. When the user does not stretch the electronic device ED8, the electronic device ED8 may be in the folding state (or the first state), as shown in the state (I) of FIG. 18. In such condition, the first portion P1 of the electronic device ED8 may be exposed, and the second portion P2 of the electronic device ED8 may be hidden. The first portion P1 may include the peripheral area PR, the first active area AR1 and the second active area AR2, wherein the transmittance of the first active area AR1 is greater than the transmittance of the second active area AR2. In the first state, the optical module (not shown) of the electronic device ED8 may overlap the first active area AR1 in the normal direction of the electronic device ED8 (for example, a direction parallel to the direction Y). In the present embodiment, the first active area AR1 and the second active area AR2 may be combined to define a main active area MR. Specifically, the main active area MR may be the active area which is exposed when the electronic device ED8 is in the folding state, or the main active area MR may be the operating area of the electronic elements EL when the electronic device ED8 is in the folding state.

The electronic device ED8 may be stretched in the unfolded-folded direction ST, such that the electronic device ED8 may be switched between the folding state and the unfolding state. In the present embodiment, the unfolded-folded direction ST may be parallel to the direction Z, such as the direction Z and the direction −Z. In other words, the electronic panel EP may move along the direction Z or the direction −Z, such that the electronic device ED8 is unfolded/folded. For example, the user may stretch the electronic panel EP along the direction Z, such that the electronic device ED8 is unfolded. As shown in the state (II) of FIG. 18, when the electronic device ED8 is stretched and in the second state (or the unfolding state), the second portion P2 of the electronic panel EP may be exposed, wherein the second portion P2 may include the third active area AR3 and the active area AR4, and the transmittance of the third active area AR3 is greater than the transmittance of the active area AR4. In the second state, the optical module (not shown) of the electronic device ED8 may overlap the third active area AR3 in the normal direction of the electronic device ED8. In the present embodiment, the third active area AR3 and the active area AR4 may be combined to define an extending active area ER. Specifically, the extending active area ER may be the active area exposed when the electronic device ED8 is in the second state, or the extending active area ER may be operated by the user when the electronic device ED8 is in the second state. In other words, when the electronic device ED8 is in the first state, the area in the electronic device ED8 that can be operated by the user may be the main active area MR; and when the electronic device ED8 is in the second state, the area in the electronic device ED8 that can be operated by the user may include the main active area MR and the extending active area ER. That is, as the degree of unfolding (or expansion) of the electronic device ED8 increases, the size of the area in the electronic device ED8 that can be operated by the user (or the active area exposed in the electronic device ED8) may increase. The definitions and other features of the main active area MR and the extending active area ER mentioned above may be applied to the embodiments of the present disclosure.

In summary, a stretchable electronic device capable of operating in the folding state and in the unfolding state is provided by the present disclosure, wherein when the electronic device is in the folding state or in the unfolding state, the optical module of the electronic device may overlap the area having a greater transmittance in the electronic panel. In addition, the supporting plate of the electronic device further includes at least one opening, such that the optical module may overlap the opening of the supporting plate when the electronic device is in the folding state or in the unfolding state. Therefore, the light receiving effect of the optical module in different states of the electronic device may be improved, thereby improving the performance of the optical module.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device capable of operating in a first state or in a second state, comprising:
an electronic panel having a first portion and a second portion, wherein the first portion has a first active area and a second active area, a transmittance of the first active area is greater than a transmittance of the second active area, and the second portion is hidden from a top view of the electronic device in the first state and exposed from the top view of the electronic device in the second state;
an optical module disposed under the electronic panel and overlapped with the first active area in the first state; and
a supporting plate disposed under the electronic panel, wherein the supporting plate has a first opening overlapped with the first active area and a plurality of second openings overlapped with the second portion.

2. The electronic device according to claim 1, wherein an area of the first opening is greater than an area of one of the plurality of second openings.

3. The electronic device according to claim 1, wherein the electronic panel and the optical module move together when the electronic device changes from the first state to the second state.

4. The electronic device according to claim 1, wherein the electronic panel further has a third portion connected to the first portion and fixed to a backside of the supporting plate.

5. The electronic device according to claim 4, further comprising a flexible printed circuit board bonded on the third portion and not overlapped with the first active area.

6. The electronic device according to claim 5, wherein a distance between the first opening and a first edge of the supporting plate is greater than a distance between the first edge of the supporting plate and an edge of the flexible printed circuit board in a horizontal direction.

7. The electronic device according to claim 1, wherein the electronic panel further has a third portion connected to the second portion and fixed to a backside of the supporting plate.

8. The electronic device according to claim 7, further comprising a flexible printed circuit board bonded on the third portion and not overlapped with the plurality of second openings.

9. The electronic device according to claim 8, wherein a distance between one of the plurality of second openings and a second edge of the supporting plate is greater than a distance between the second edge and an edge of the flexible printed circuit board in a horizontal direction.

10. The electronic device according to claim 1, wherein the electronic panel moves relative to the optical module when the electronic device changes from the first state to the second state.

11. The electronic device according to claim 10, wherein the second portion has a third active area, a transmittance of the third active area is greater than the transmittance of the second active area, the first active area is overlapped with the optical module in the first state, and the third active area is overlapped with the optical module in the second state.

12. The electronic device according to claim 11, wherein the first active area is separated from the third active area.

13. The electronic device according to claim 12, wherein an edge of the electronic panel moves along a direction by a distance S1 when the electronic device changes from the first state to the second state, the first active area has a width Wa, the first active area is separated from the third active area by a distance D1, wherein the distance S1, the width Wa, and the distance D1 satisfy a following equation:
D1=S1−Wa.

14. The electronic device according to claim 11, wherein the first active area is connected to the third active area.

15. The electronic device according to claim 14, wherein an edge of the electronic panel moves along a direction by a distance S1 when the electronic device changes from the first state to the second state, the optical module has an aperture, the aperture has a width Wc, and a sum of a width of the first active area and a width of the third active area is a width Wb, wherein the distance S1, the width Wb, and the width Wc satisfy a following equation:
Wb≥S1+Wc.

16. The electronic device according to claim 10, wherein the supporting plate further has a third opening overlapped with the second portion, the first opening is overlapped with the optical module in the first state, and the third opening is overlapped with the optical module in the second state.

17. The electronic device according to claim 16, wherein an area of the third opening is greater than an area of one of the plurality of second openings.

18. The electronic device according to claim 16, wherein the third opening is separated from the first opening.

19. The electronic device according to claim 16, wherein the third opening is connected to the first opening.

20. The electronic device according to claim 1, further comprising another optical module, wherein the electronic panel has a fourth active area, a transmittance of the fourth active area is less than the transmittance of the first active area and greater than the transmittance of the second active area, and the another optical module is overlapped with the fourth active area in the first state.
